(19) United States
(12) Patent Application Publication
(10) Pub. No.: US 2018/0293025 A1
(43) Pub. Date: Oct. 11, 2018

(54) INTERFACE CIRCUIT, MEMORY DEVICE, INFORMATION PROCESSING SYSTEM, AND INTERFACE CIRCUIT CONTROLLING METHOD

(71) Applicant: SONY CORPORATION, Tokyo (JP)

(72) Inventors: Lui SAKAI, Kanagawa (JP); Yoshiyuki SHIBAHARA, Tokyo (JP); Tetsuo YOSHIDA, Kanagawa (JP); Hidenobu KAKIOKA, Tokyo (JP); Haruhiko TERADA, Kanagawa (JP)

(21) Appl. No.: 15/522,383

(22) PCT Filed: Oct. 8, 2015
(86) PCT No.: PCT/JP2015/078607

§ 371 Date: Apr. 27, 2017

(30) Foreign Application Priority Data
Nov. 10, 2014 (JP) 2014-227704

(51) Int. Cl. G06F 3/06; G06F 11/10; G11C 29/52

(52) U.S. Cl. CPC G06F 3/0659; G06F 3/0604; G11C 29/52; G06F 11/1068; G06F 3/0679

(57) ABSTRACT

To enable data to be transferred between a memory and a memory controller with accuracy. A memory-side interface circuit synchronizes a first periodic signal having a greater number of cycles than a number of pieces of unit data obtained by dividing read data read from a memory cell by a predetermined unit with the unit data and to sequentially transmit the first periodic signal and the unit data. A controller-side interface circuit sequentially holds the transmitted unit data in holding units of a plurality of stages in synchronization with the periodic signal and sequentially reads and outputs the held unit data in synchronization with a second periodic signal.

### TECHNICAL FIELD

The present technology relates to an interface circuit, a memory device, an information processing system, and an interface circuit controlling method. Particularly, the technology relates to an interface circuit, a memory device, an information processing system, and an interface circuit controlling method which enable data to be transmitted and received in synchronization with a strobe signal.

### BACKGROUND ART

Non-volatile memories (NVMs) have been used as auxiliary storage devices or storages in recent information processing systems. Non-volatile memories are broadly divided into flash memories for data access in units of large data sizes and non-volatile random access memories (Non-volatile RAMs) to which high-speed random access is possible in units of smaller data sizes. Here, NAND flash memories are exemplified as a representative example of flash memories. On the other hand, resistance RAMs (ReRAMs), phase-change RAMs (PCRAIVIs), magnetoresistive RAMs (MRAMs), and the like are exemplified as examples of non-volatile random access flash memories.

Such a non-volatile memory transfers data to a memory controller in synchronization with a strobe signal in general. Then, the memory controller holds the data from the non-volatile memory in flip-flops in synchronization with the strobe signal, and takes out and processes the held data in synchronization with an internal clock signal.

Here, to take out a signal in synchronization with an internal clock signal of a memory controller, for example, a method of holding data in flip-flops of a plurality of stages in synchronization with a strobe signal and taking out the data is used. When the number of cycles of a strobe signal is equal to the number of pieces of data in such a configuration in which data is held in flip-flops of a plurality of stages, there is concern of all of the data not being output from the flip-flop of the final stage. In this case, the memory controller fails to take out some data. Thus, a memory controller in which a delay control circuit that adjusts a delay time of a strobe signal is provided so that all data can be taken out has been proposed (refer to, for example, Patent Literature 1).

### CITATION LIST

### Patent Literature

Patent Literature 1: JP 2006-12363A

### DISCLOSURE OF INVENTION

### Technical Problem

In the above-described related art, however, as a speed of data transfer between a memory controller and a memory becomes higher, accuracy required to control a delay time gets higher. As a method of increasing accuracy in control, for example, a method in which an oscillator circuit that generates a clock signal having a higher frequency than a transfer frequency is provided and oversampling is performed on data using the clock signal and a method of reducing a delay time of a delay element are known. When oversampling is to be performed, it is necessary to further provide a circuit or an oscillator circuit that performs oversampling, which causes the circuit to become complicated, and eventually component costs and design costs increase. In addition, when delay elements with short delay times are provided, the number of delay elements that are necessary for causing a delay of a unit time increases, and thus component costs and design costs increase likewise. In particular, when circuits are practically mounted using a field-programmable gate array (FPGA), it is necessary to use basic cells provided by an FPGA vendor, however, performance of these basic cells is fixed. For this reason, design is difficult when it is desired to make a transfer speed higher than a speed that corresponds to the performance of the basic cells, or the like. Thus, as a data transfer speed becomes higher, a delay time is more difficult to control, and thus there is concern of data not being transferred with accuracy.

The present technology has been conceived in consideration of the above circumstances, and aims to enable data to be transferred between a memory and a memory controller with accuracy.

### Solution to Problem

The present technology has been devised to solve the above-described problem, and a first aspect thereof is an interface circuit and a control method thereof, the interface circuit including: a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and a controller-side interface circuit configured to sequentially hold the transmitted unit data in holding units of a plurality of stages in synchronization with the first periodic signal and to sequentially read and output the held unit data in synchronization with a second periodic signal. Accordingly, the effect is exhibited that unit data and a periodic signal having the greater number of cycles than the number of pieces of the unit data are sequentially transmitted in synchronization with each other.

Further, according to the first aspect, the controller-side interface circuit may transmit a read command for instructing reading of the read data to the memory-side interface circuit. The memory-side interface circuit may read the read data in accordance with the read command, synchronize the unit data with the first periodic signal having the same number of cycles as the number of pieces of the unit data, and sequentially transmit the first periodic signal and the unit data. The controller-side interface circuit may transmit a periodic signal transmission command for instructing transmission of the first periodic signal to the memory-side interface circuit after the transmission of the read command. The memory-side interface circuit may transmit the first periodic signal having a predetermined number of cycles in accordance with the periodic signal transmission command. Accordingly, the effect is exhibited that a periodic signal having the predetermined number of cycles is transmitted in accordance with a periodic signal transmission command.

Further, according to the first aspect, the controller-side interface circuit may transmit a read command for instructing reading of the read data to the memory-side interface circuit. The memory-side interface circuit may read the read data in accordance with the read command, synchronize the unit data with the first periodic signal having the same number of cycles as the number of pieces of the unit data, and sequentially transmit the first periodic signal and the unit data, and further transmit the first periodic signal having a predetermined number of cycles. Accordingly, the effect is exhibited that unit data and a periodic signal having the same number of cycles as the number of pieces of the unit data are sequentially transmitted in synchronization with each other, and a periodic signal having a predetermined number of cycles is further transmitted.

Further, according to the first aspect, in a non-transmission period in which the read data is not transmitted, the memory-side interface circuit may repeatedly transmit the first periodic signal until the number of cycles transmitted within the non-transmission period reaches the predetermined number of cycles. Accordingly, the effect is exhibited that a periodic signal is repeatedly transmitted until the number of cycles transmitted within a non-transmission period reaches a predetermined number of cycles.

Further, according to the first aspect, the controller-side interface circuit may transmit a setting command for setting a predetermined number of cycles to the memory-side interface circuit. Accordingly, the effect is exhibited that a setting command for setting a predetermined number of cycles is transmitted.

Further, according to the first aspect, the controller-side interface circuit may transmit a start command for instructing transmission of a predetermined number of pieces of pattern data to the memory-side interface circuit. The memory-side interface circuit may synchronize the first periodic signal having the same number of cycles as the predetermined number with the pattern data in accordance with the start command, and transmit the first periodic signal and the pattern data to the controller-side interface circuit. The controller-side interface circuit may sequentially hold the transmitted pattern data in the holding units of the plurality of stages in synchronization with the first periodic signal, sequentially read the held pattern data in synchronization with the second periodic signal, and transmit the setting command for setting a difference between the number of pieces of the read pattern data and the predetermined number to the memory-side interface circuit. Accordingly, the effect is exhibited that the difference between the number of pieces of read pattern data and a predetermined number is set as the number of cycles.

Further, according to the first aspect, the unit data may include first and second data. The memory-side interface circuit may transmit the first data in synchronization with a rise of the first periodic signal, and transmit the second data in synchronization with a fall of the first periodic signal. Accordingly, the effect is exhibited that first data is transmitted in synchronization with a rise of the periodic signal and the second data is transmitted in synchronization with a fall of the periodic signal.

Further, a second aspect of the present technology is a memory device including: a memory cell; and an interface circuit configured to synchronize a periodic signal having a greater number of cycles than a number of pieces of unit data obtained by dividing read data read from the memory cell by a predetermined unit with the unit data and to sequentially transmit the periodic signal and the unit data. Accordingly, the effect is exhibited that unit data and a periodic signal having a greater number of cycles than the number of pieces of the unit data are sequentially transmitted in synchronization with each other.

Further, a third aspect of the present technology is an information processing system including: a memory cell; a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and a controller-side interface circuit configured to sequentially hold the transmitted unit data in holding units of a plurality of stages in synchronization with the first periodic signal and to sequentially read and output the held unit data in synchronization with a second periodic signal. Accordingly, the effect is exhibited that unit data and a periodic signal having a greater number of cycles than the number of pieces of the unit data are sequentially transmitted in synchronization with each other.

### Advantageous Effects of Invention

According to the present technology, an excellent effect that data is accurately transferred between a memory and a memory controller can be exhibited. Note that the effects described here are not necessarily limited, and any effect that is desired to be described in the present disclosure may be exhibited.

### BRIEF DESCRIPTION OF DRAWINGS

FIG. 1 is a block diagram illustrating a configuration example of an information processing system according to a first embodiment.

FIG. 2 is a block diagram illustrating an example of a configuration of a memory controller according to the first embodiment.

FIG. 3 is a block diagram illustrating an example of a functional configuration of the memory controller according to the first embodiment.

FIG. 4 is a diagram illustrating a configuration example of a controller-side interface circuit according to the first embodiment.

FIG. 5 is a circuit diagram illustrating configuration examples of a clock-enable transmission unit and a clock transmission unit according to the first embodiment.

FIG. 6 is a block diagram illustrating a configuration example of a data reception unit according to the first embodiment.

FIG. 7 is a circuit diagram illustrating a configuration example of a serial-parallel conversion unit and a clock transfer unit according to the first embodiment.

FIG. 8 is a block diagram illustrating a configuration example of a non-volatile memory according to the first embodiment.

FIG. 9 is a block diagram illustrating a configuration example of a memory-side interface circuit according to the first embodiment.

FIG. 10 is a circuit diagram illustrating configuration examples of a clock-enable reception unit and a strobe transmission unit according to the first embodiment.

FIG. 11 is a circuit diagram illustrating a configuration example of a data reception unit according to the first embodiment.

FIG. 12 is a block diagram illustrating a configuration example of a memory control unit according to the first embodiment.

FIG. 13 is a flowchart showing an example of an operation of a storage according to the first embodiment.

FIG. 14 is a flowchart showing an example of a read process according to the first embodiment.

FIG. 15 shows timing charts of examples of timings at which a memory controller and a non-volatile memory transmit and receive signals according to the first embodiment.

FIG. 16 is a timing chart illustrating an example of timings at which the memory controller holds data according to the first embodiment.

FIG. 17 is a timing chart illustrating an example of timings at which the memory controller holds data according to a comparative example of the first embodiment.

FIG. 18 is a circuit diagram illustrating a configuration example of a data reception unit according to the modified example of the first embodiment.

FIG. 19 is a block diagram illustrating an example of a functional configuration of the memory controller according to the second embodiment.

FIG. 20 is a block diagram illustrating a configuration example of a memory control unit according to the second embodiment.

FIG.21 is a flowchart showing an example of a read process according to the second embodiment.

FIG. 22 shows timing charts of examples of timings at which a memory controller and a non-volatile memory transmit and receive signals according to the second embodiment.

FIG. 23 is a flowchart showing an example of a read process according to a modified example of the second embodiment.

FIG. 24 shows timing charts of examples of timings at which a memory controller and a non-volatile memory transmit and receive signals according to the modified example of the second embodiment.

FIG. 25 is a block diagram illustrating an example of a functional configuration of the memory controller according to the third embodiment.

FIG. 26 is a block diagram illustrating a configuration example of a memory control unit according to the third embodiment.

FIG. 27 is a flowchart showing an example of an operation of a storage according to the third embodiment.

FIG. 28 is a block diagram illustrating an example of a functional configuration of the memory controller according to the fourth embodiment.

FIG. 29 is a block diagram illustrating a configuration example of a memory control unit according to the fourth embodiment.

FIG. 30 is a flowchart showing an example of an operation of a storage according to the fourth embodiment.

FIG. 31 is a flowchart showing an example of a number-of-strobe-issuance-operations setting process according to a fourth embodiment.

FIG. 32 shows timing charts of examples of timings at which a memory controller and a non-volatile memory transmit and receive signals according to the second embodiment.

### MODE(S) FOR CARRYING OUT THE INVENTION

Exemplary embodiments of the present technology (which will be referred to as embodiments below) will be described hereinbelow. Description will be provided in the following order.
1. First embodiment (example in which strobe signals greater in number than pieces of data are transmitted)
2. Second embodiment (example in which strobe signals greater in number than pieces of data are transmitted without receiving strobe issuance command)
3. Third embodiment (example in which strobe signal having set larger number of cycles than pieces of data is transmitted)
4. Fourth embodiment (example in which strobe signal having large number of cycles computed on basis of number of pieces of data is transmitted)

### 1. First Embodiment

### [Configuration Example of Information Processing System]

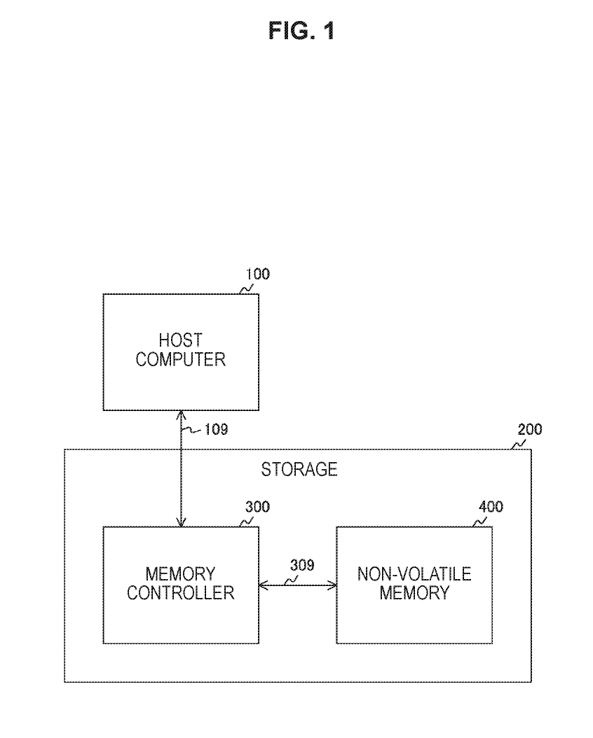

FIG. 1 is a block diagram illustrating a configuration example of an information processing system according to an embodiment. This information processing system includes a host computer 100 and a storage 200.

The host computer 100 controls the information processing system overall. The host computer 100 generates access requests and write data, and supplies the requests and data to the storage 200 via a signal line 109. The access requests include a write request for requesting writing of write data, and a read request instructing reading of read data. In addition, the host computer 100 receives read data from storage 200.

The storage 200 includes a memory controller 300 and a non-volatile memory 400. The memory controller 300 controls the non-volatile memory 400. The memory controller 300 converts write data into code words of error detection and correction codes (ECC) according to a write request. The memory controller 300 issues a write command as an access command, accesses the non-volatile memory 400 via a signal line 309, and writes encoded write data thereon.

In addition, when a read request from the host computer 100 is received, the memory controller 300 issues a read command as an access command. The memory controller 300 accesses the non-volatile memory 400 and reads encoded read data therefrom in accordance with the read command. Then, the memory controller 300 converts (i.e., decodes) the encoded read data into original data before encoding. In addition, the memory controller 300 performs error detection and correction on the read data on the basis of ECC. The memory controller 300 supplies the corrected read data to the host computer 100.

The non-volatile memory 400 stores data according to control of the memory controller 300. For example, a ReRAM is used as the non-volatile memory 400. The non-volatile memory 400 includes a plurality of memory cells, and the memory cells are divided into a plurality of blocks. Here, a block refers to a unit of access to the non-volatile memory 400 and is also called a sector. A physical address is assigned to each of the blocks. Note that, a flash memory, a PCRAM, an MRAM, or the like may be used as the non-volatile memory 400 instead of a ReRAM. Note that the non-volatile memory 400 is an example of the memory device described in the claim.

### [Configuration Example of Memory Controller]

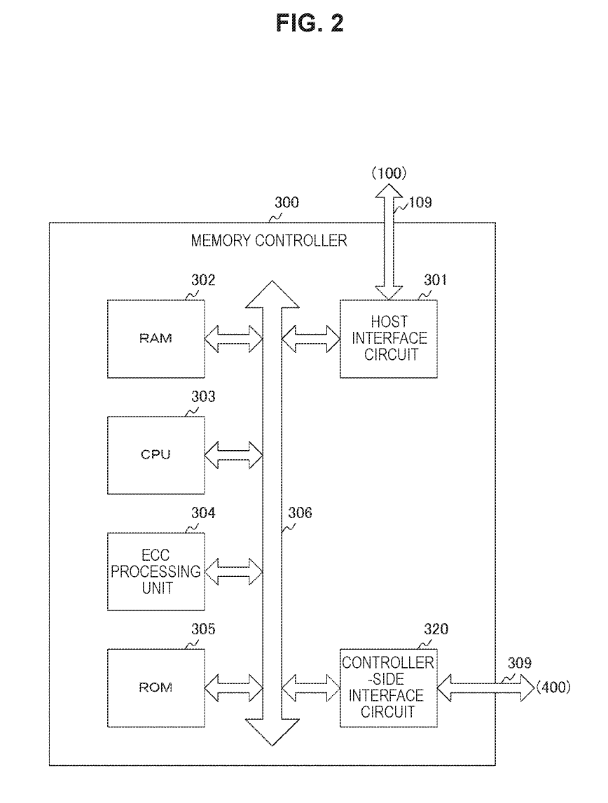

FIG. 2 is a block diagram illustrating a configuration example of the memory controller 300 according to a first embodiment. The memory controller 300 includes a random access memory (RAM) 302, a central processing unit (CPU) 303, an ECC processing unit 304, and a read only memory (ROM) 305. In addition, the memory controller 300 includes a host interface circuit 301, a bus 306, and a controller-side interface circuit 320.

The RAM 302 temporarily holds data necessary for the CPU 303 to execute processes. The CPU 303 controls the memory controller 300 overall. The ROM 305 stores programs and the like executed by the CPU 303. The host interface circuit 301 exchanges data and access requests with the host computer 100. The bus 306 is a common path on which the RAM 302, the CPU 303, the ECC processing unit 304, the ROM 305, the host interface circuit 301, and the controller-side interface circuit 320 exchange data with each other. The controller-side interface circuit 320 performs transmission and reception of data and commands with the non-volatile memory 400.

The ECC processing unit 304 encodes write data, and decodes encoded read data.

### [Configuration Example of Memory Controller]

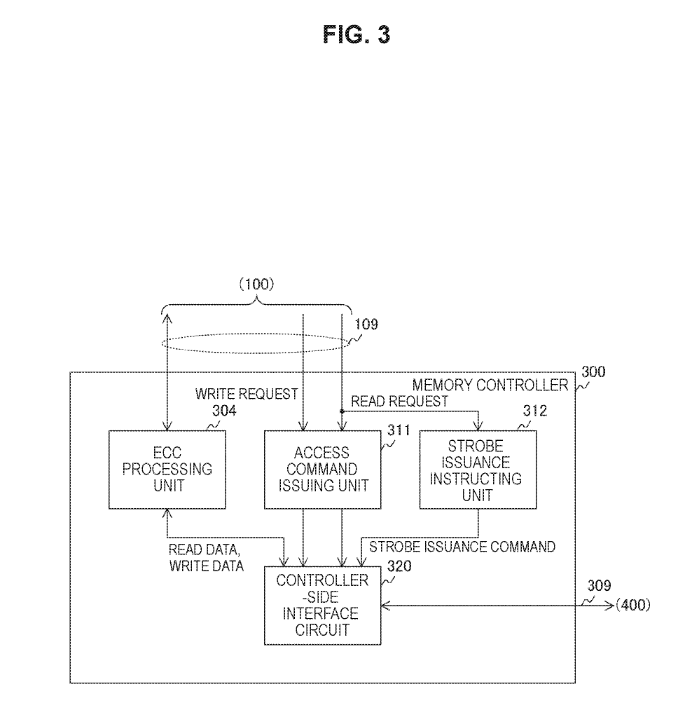

FIG. 3 is a block diagram illustrating a functional configuration example of the memory controller 300 according to the first embodiment. The memory controller 300 includes the ECC processing unit 304, an access command issuing unit 311, a strobe issuance instructing unit 312, and the controller-side interface circuit 320.

The access command issuing unit 311 of FIG. 3 is realized by the RAM 302, the CPU 303, the ECC processing unit 304, the ROM 305, the host interface circuit 301, the bus 306, and the controller-side interface circuit 320, and the like of FIG. 2. The same applies to the strobe issuance instructing unit 312.

The access command issuing unit 311 issues an access command in accordance with an access request. The access command issuing unit 311 converts, for example, a logical address designated by an access request into a physical address. Here, a logical address is an address assigned per unit of access to the storage 200 by the host computer 100 in an address space defined by the host computer 100 or the memory controller 300. In addition, a physical address is an address of the non-volatile memory 400 assigned per unit of access to the non-volatile memory 400 by the memory controller 300.

In addition, the access command issuing unit 311 issues an access command for designating a converted physical address. When a unit of access of the host computer 100 is different from a unit of access of the non-volatile memory 400, a plurality of access commands are issued on the basis of one access request when necessary. The access command issuing unit 311 supplies an issued access command to the controller-side interface circuit 320.

The strobe issuance instructing unit 312 issues a strobe issuance command after transmission of a read command. The strobe issuance command instructs issuance of a periodic signal having a predetermined number of cycles E as a strobe signal without accompanying valid data. Here, E is an integer, and for example, is set as “2.” In addition, valid data means individual pieces of data obtained by dividing read data by a unit of transmission, and data that is not included in the read data is treated as invalid data. When a read command is received, the non-volatile memory 400 synchronizes valid data with a strobe signal and sequentially transmits the data and the signal to the memory controller 300. On the other hand, when a strobe issuance command is received, the non-volatile memory 400 sequentially transmits invalid data and a strobe signal to the memory controller 300. Note that a strobe signal is an example of the first periodic signal described in the claims. In addition, a strobe issuance command is an example of the periodic signal transmission command described in the claims.

### [Configuration Example of Controller-Side Interface Circuit]

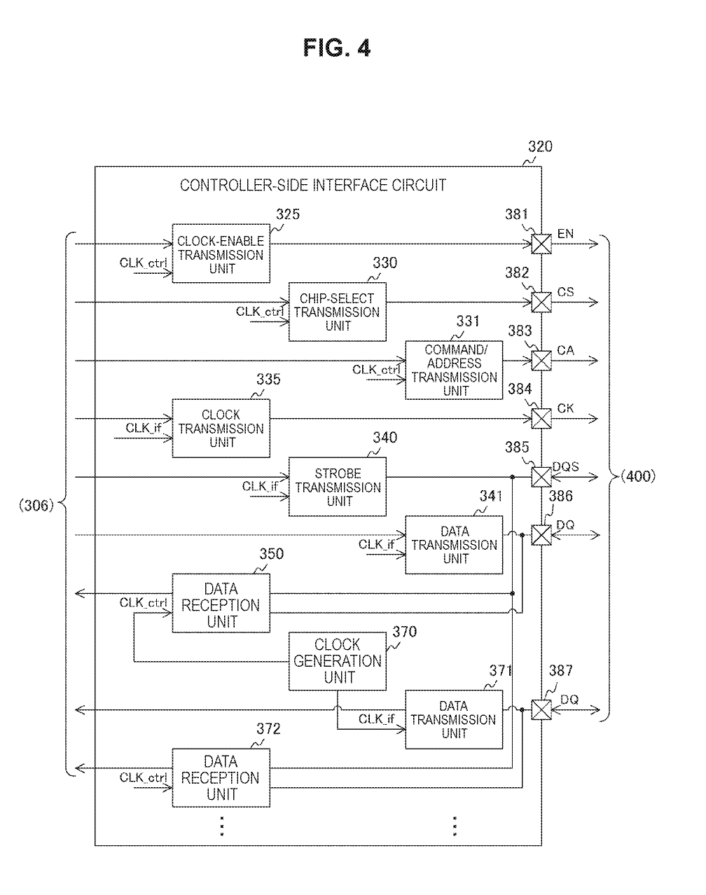

FIG. 4 is a block diagram illustrating a configuration example of the controller-side interface circuit 320. The controller-side interface circuit 320 includes a clock-enable transmission unit 325, a chip-select transmission unit 330, a command/address transmission unit 331, a clock transmission unit 335, and a strobe transmission unit 340. In addition, the controller-side interface circuit 320 includes a data transmission unit 341, a data reception unit 350, a clock generation unit 370, a data transmission unit 371, a data reception unit 372, and terminals 381 to 387.

The clock-enable transmission unit 325 transmits a clock-enable signal EN to the non-volatile memory 400 in synchronization with a clock signal CLK_ctrl via an enable line connected to the terminal 381. The clock-enable signal EN is a signal for instructing whether or not a base clock signal transmitted from the memory controller 300 to the non-volatile memory 400 is set to be valid in the non-volatile memory 400.

The chip-select transmission unit 330 transmits a chip-select signal CS to the non-volatile memory 400 in synchronization with the clock signal CLK_ctrl via a signal line connected to the terminal 382. The chip-select signal CS is a signal for instructing whether or not an access command with respect to the non-volatile memory 400 is set to be valid.

The command/address transmission unit 331 transmits a command and address CA to the non-volatile memory 400 in synchronization with the clock signal CLK_ctrl via a command/address line connected to the terminal 383.

The clock transmission unit 335 supplies a base clock signal CK to the non-volatile memory 400 in synchronization with a clock signal CLK_if via a signal line connected to the terminal 384. The base clock signal CK is a reference clock signal used by the non-volatile memory 400. In addition, a frequency of the clock signal CLK_if is set to be k (k is an integer) times the above-described clock signal CLK_crtl.

The strobe transmission unit 340 transmits a strobe signal DQS to the non-volatile memory 400 in synchronization with the clock signal CLK_if via a strobe line connected to the terminal 385. The data transmission unit 341 transmits write data to the non-volatile memory 400 as data DQ in units of transmission in synchronization with the clock signal CLK_if via a data line connected to the terminal 386. Due to the strobe transmission unit 340 and the data transmission unit 341, the data DQ included in the write data and the strobe signal are sequentially transferred in synchronization with each other.

The data reception unit 350 receives data DQ from the non-volatile memory 400 via the data line of the terminal 386. The data reception unit 350 receives a strobe signal from the non-volatile memory 400 via the strobe line connected to the terminal 385, and sequentially holds the data DQ in synchronization with the strobe signal. In addition, the data reception unit 350 sequentially takes out the held data DQ in synchronization with the clock signal CLK_ctrl and supplies the data to the ECC processing unit 304 via the bus 306.

Here, a frequency of the clock signal CLK_ctrl is set to be the same as that of the strobe signal DQS. Note that frequencies of the signals may be configured to be different from each other. In addition, the clock signal CLK_ctrl is an example of the second periodic signal described in the claims.

The clock generation unit 370 generates clock signals CLK_ctrl and CLK_if. The clock generation unit 370 supplies the generated clock signal CLK_ctrl to the clock-enable transmission unit 325, the chip-select transmission unit 330, the command/address transmission unit 331, the data reception unit 350, and the data reception unit 372. In addition, the clock generation unit 370 supplies the generated clock signal CLK_if to the clock transmission unit 335, the strobe transmission unit 340, the data transmission unit 341, and the data transmission unit 371.

The data transmission unit 371 is configured similarly to the data transmission unit 341 except that the former transmits data via a data line connected to the terminal 387. The data reception unit 372 is configured similarly to the data reception unit 350 except that the former receives data via the data line connected to the terminal 387.

Note that the controller-side interface circuit 320 has not only a transmission/reception circuit constituted by the data transmission unit 341 and the data reception unit 350 and a transmission/reception circuit constituted by the data transmission unit 371 and the data reception unit 372 but also a plurality of transmission/reception circuits having the same configurations. For example, 8 transmission/reception circuits are provided in total, and data is transmitted and received via 8 data lines. In FIG. 4, however, only 2 of the 8 transmission/reception circuits are described for the sake of convenience in description, and the other 6 transmission/reception circuits are omitted. Likewise for the data lines, only 2 of the 8 data lines are described, and the other 6 data lines are omitted.

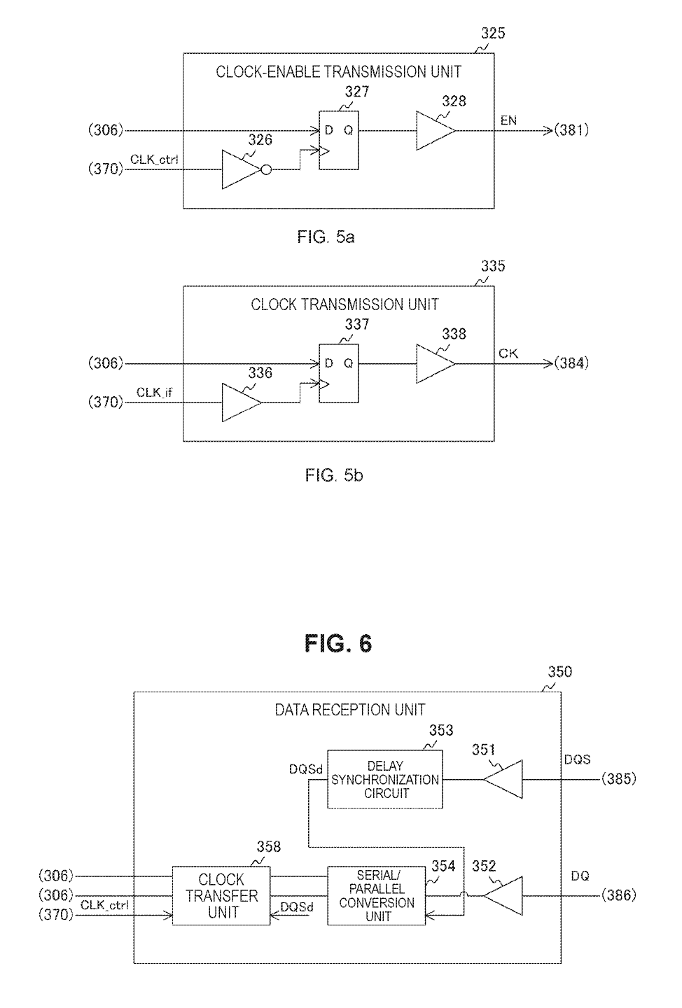

FIG. 5 is a circuit diagram illustrating configuration examples of the clock-enable transmission unit 325 and the clock transmission unit 335 according to the first embodiment. a of the diagram is a circuit diagram of a configuration example of the clock-enable transmission unit 325, and b of the diagram is a circuit diagram illustrating a configuration example of the clock transmission unit 335.

The clock-enable transmission unit 325 includes an inverter 326, a flip-flop 327, and a driver 328. The inverter 326 inverts the clock signal CLK_ctrl and supplies the signal to the flip-flop 327. The flip-flop 327 holds a clock-enable signal EN in synchronization with the inverted clock signal CLK_ctrl, and outputs the signals to the driver 328. The driver 328 transmits the clock-enable signal EN to the non-volatile memory 400 via the terminal 381.

Note that respective configurations of the chip-select transmission unit 330, the command/address transmission unit 331, the data transmission unit 341, and the data transmission unit 371 are similar to that of the clock-enable transmission unit 325.

The clock transmission unit 335 includes a buffer 336, a flip-flop 337, and a driver 338. The buffer 336 supplies the clock signal CLK_if to the flip-flop 337. The flip-flop 337 holds the base clock signal CK in synchronization with the clock signal CLK_ctrl, and outputs the signals to the driver 338. The driver 338 transmits the base clock signal CK to the non-volatile memory 400 via the terminal 384. Note that a configuration of the strobe transmission unit 340 is similar to that of the clock transmission unit 335.

### [Configuration Example of Data Reception Unit]

FIG. 6 is a block diagram illustrating a configuration example of the data reception unit 350 according to the first embodiment. The data reception unit 350 includes receivers 351 and 352, a delay synchronization circuit 353, a serial/parallel conversion unit 354, and a clock transfer unit 358.

The receiver 351 receives a strobe signal DQS, a preamble signal, and a postamble signal via the terminal 385. Here, the preamble signal is a signal output prior to output of data, and a low level signal is output as a preamble signal over, for example, 1 clock period of the clock signal CLK_ctrl. In addition, the postamble signal is a signal output after output of data, and a low level signal is output over, for example, 1.5 clock periods of the clock signal CLK_ctrl. The receiver 351 receives the strobe signal DQS after a preamble signal is detected until a postamble signal is detected, and supplies the signal to the delay synchronization circuit 353.

The delay synchronization circuit 353 shifts a phase of the strobe signal DQS by 90 degrees. The delay synchronization circuit 353 supplies a strobe signal DQSd whose phase has been shifted to the serial/parallel conversion unit 354 and the clock transfer unit 358.

The receiver 352 receives valid data DQ. The receiver 352 supplies the received data DQ to the serial/parallel conversion unit 354. Here, the data DQ is data transferred in a double data rate (DDR) scheme, and includes data transferred in synchronization with a rise of a strobe signal and data transferred in synchronization with a fall of the signal.

The serial/parallel conversion unit 354 divides, in synchronization with the strobe signal DQSd, the data DQ into data transferred in synchronization with a rise of the signal and data transferred in synchronization with a fall thereof. The serial/parallel conversion unit 354 supplies the respective divided pieces of the data to the clock transfer unit 358.

The clock transfer unit 358 is a unit for holding the respective pieces of the data divided by the serial/parallel conversion unit 354 in holding units such as flip-flops in synchronization with the strobe signal DQSd and reading the data in synchronization with the clock signal CLK_ctrl. The clock transfer unit 358 supplies the read data to the ECC processing unit 304 via the bus 306.

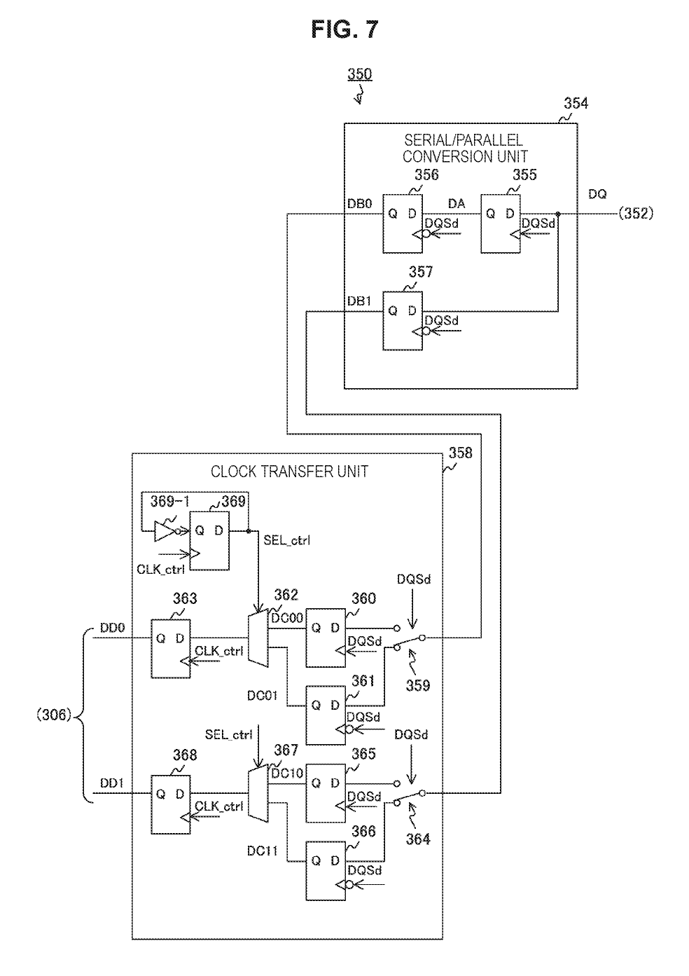

FIG. 7 is a circuit diagram illustrating a configuration example of the serial/parallel conversion unit 354 and the clock transfer unit 358 according to the first embodiment.

The serial/parallel conversion unit 354 includes flip-flops 355, 356, and 357. In addition, the clock transfer unit 358 includes switches 359 and 364, flip-flops 360, 361, 363, 365, 366, 368, and 369, an inverter 369-1, and selectors 362 and 367. Note that the flip-flops 355, 356, and 357 and the flip-flops 360, 361, 363, 365, 366, and 368 are examples of the holding units described in the claims.

The flip-flop 355 holds data DQ as data DA in synchronization with the strobe signal DQSd, and outputs the data to the flip-flop 356. The flip-flop 356 holds the data DA in synchronization with the inverted strobe signal DQSd as data DBO, and outputs the data to the switch 359. The data DBO is data transferred in synchronization with a rise of a strobe signal. The flip-flop 357 holds the data DA as data DB1 in synchronization with a signal obtained by inverting the strobe signal DQSd, and outputs the data to the switch 364. The data DB1 is data transferred in synchronization with a fall of the strobe signal.

The switch 359 switches an output destination of the data DBO between the flip-flops 360 and 361 in synchronization with the strobe signal DQSd. For example, an output destination of the data DBO is switched each time one cycle of the strobe signal DQSd elapses.

The flip-flop 360 holds the data DBO from the switch 359 as data DC00 in synchronization with the strobe signal DQSd and supplies the data to the selector 362. The flip-flop 361 holds the data DBO from the switch 359 as data DC01 in synchronization with the inverted strobe signal DQSd, and supplies the data to the selector 362.

A flip-flop 369 holds a selector control signal SEL_ctrl in synchronization with a rise of the clock signal CLK_ctrl. The flip-flop 369-1 supplies the selector control signal SEL_ctrl to the selectors 362 and 367, and the inverter 369-1. The inverter 369-1 inverts the selector control signal SEL_ctrl from an output terminal of the flip-flop 369 and supplies the signal to an input terminal of the flip-flop 369. The selector 362 selects one of the pieces of the data DC00 and DC01 in accordance with the selector control signal SEL_ctrl and outputs the result to the flip-flop 363. In accordance with the selector control signal SEL_ctrl, the selector 362 switches data to be selected, for example, each time a clock cycle of the clock signal CLK_ctrl elapses.

The flip-flop 363 holds the data from the selector 362 as data DDO in synchronization with the clock signal CLK_ctrl and outputs the data to the bus 306.

The switch 364 switches an output destination of the data DB1 between the flip-flops 365 and 366 in synchronization with the strobe signal DQSd of 1 cycle. An output destination of the data DB1 is switched, for example, each time 1 cycle of the strobe signal DQSd elapses.

The flip-flop 365 holds the data DB1 from the switch 364 as data DC10 in synchronization with the strobe signal DQSd. The flip-flop 366 holds the data DB1 from the switch 364 as data DC11 in synchronization with the inverted strobe signal DQSd and supplies the data to the selector 367.

The selector 367 selects one of the pieces of the data DC10 and DC11 in accordance with the selector control signal SEL_ctrl and outputs the data to the flip-flop 368. In accordance with the selector control signal SEL_ctrl, the selector 367 switches data to be selected, for example, each time a clock cycle of the clock signal CLK_ctrl elapses.

The flip-flop 368 holds the data from the selector 367 as data DD1 in synchronization with the clock signal CLK_ctrl, and outputs the data to the bus 306.

As described above, the data reception unit 350 includes the flip-flops of the plurality of stages (355, 356, and 360). The flip-flops sequentially hold data in synchronization with the strobe signal DQSd. Thus, at the time point at which the strobe signal DQSd of which the number of cycles is the same as the number of pieces of the data DQ are supplied, the last piece of the data DQ that is transmitted is not held in the flip-flop of the final stage (the flip-flop 360, or the like), but stays in the flip-flop in the stage prior thereto. However, a strobe signal having the number of cycles E is further transmitted due to a strobe issuance command. Thus, due to the extra-issued strobe signals, the data staying in the prior stage is extracted to the flip-flop of the final stage, and thus the data reception unit 350 can take out all of the data. For the number of cycles E, a fixed greater value is set in advance as the number of stages of flip-flops that operate in synchronization with a strobe signal becomes higher.

### [Example of Configuration of Non-Volatile Memory]

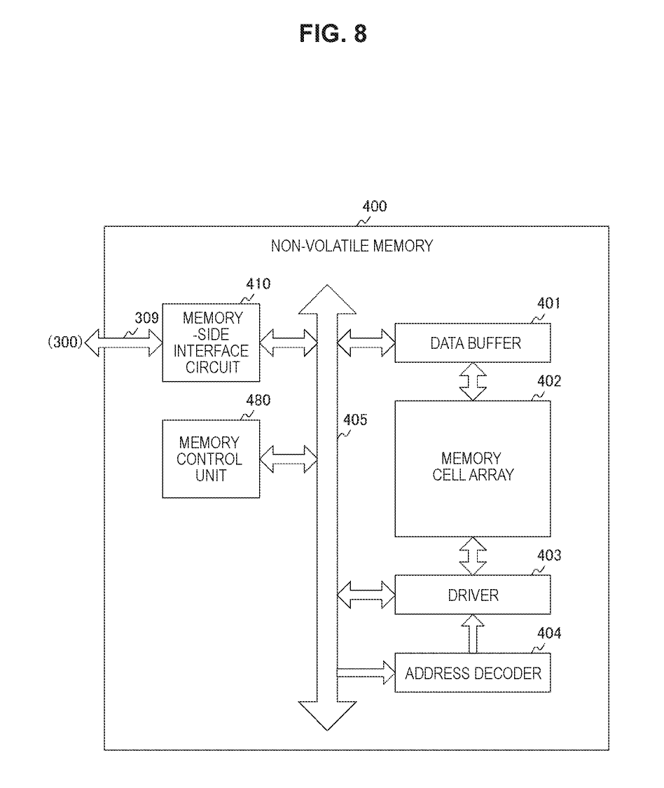

FIG. 8 is a block diagram illustrating an example of a configuration of the non-volatile memory 400 according to the first embodiment. The non-volatile memory 400 includes a data buffer 401, a memory cell array 402, a driver 403, an address decoder 404, a bus 405, a memory-side control interface circuit 410, and a memory control unit 480.

The data buffer 401 holds write data and read data in access units according to control of the memory control unit 480. The memory cell array 402 includes a plurality of memory cells arrayed in a matrix shape. Non-volatile memory elements are used as each of the memory cells. Specifically, a NAND-type or NOR-type flash memory, a ReRAM, a PCRAM, a MRAM, and the like are used as the memory elements.

The driver 403 causes data writing or data reading to be performed on a memory cell selected by the address decoder 404. The address decoder 404 analyzes an address designated by a command and selects a memory cell corresponding to the address. The bus 450 is a path shared by the data buffer 401, the memory cell array 402, the address decoder 404, the memory control unit 480, and the memory-side interface circuit 410 for mutually exchanging data. The memory-side interface circuit 410 is an interface through which the memory controller 300 and the non-volatile memory 400 transmit and receive data and commands. The memory-side interface circuit 410 synchronizes a strobe signal having the number of cycles greater than the number of pieces of the data DQ with the data DQ and transmits the signal and the data when read data including the data DQ is transmitted to the memory controller 300.

The memory control unit 480 controls a driver 403 and an address decoder 404 such that writing or reading of data is performed. In addition, the memory control unit 480 issues a strobe signal and supplies the signal to the memory-side interface circuit 410.

### [Configuration Example of Memory-Side Interface Circuit]

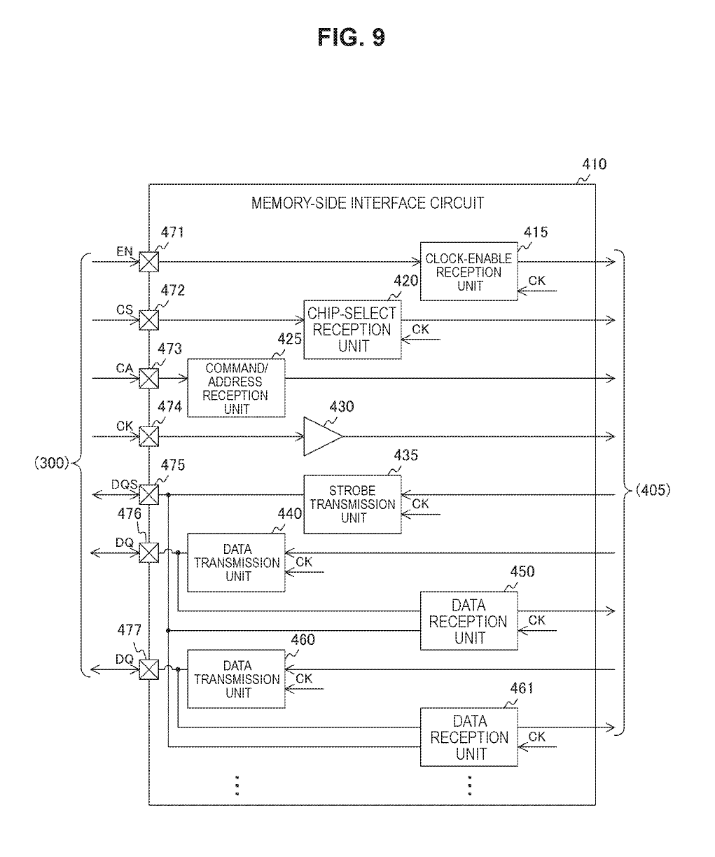

FIG. 9 is a block diagram illustrating a configuration example of the memory-side interface circuit 410 according to the first embodiment. The memory-side interface circuit 410 includes a clock-enable reception unit 415, a chip-select reception unit 420, a command/address reception unit 425, and a receiver 430. In addition, the memory-side interface circuit 410 includes a strobe transmission unit 435, a data transmission unit 440, a data reception unit 450, a data transmission unit 460, a data reception unit 461, and terminals 471 to 477.

The clock-enable reception unit 415 receives a clock-enable signal EN in synchronization with a base clock signal CK via a signal line connected to a terminal 471. The chip-select reception unit 420 receives a chip-select signal CS in synchronization with the base clock signal CK via a signal line connected to a terminal 472. The command/address reception unit 425 receives a command and address CA in synchronization with the base clock signal CK via a command/address line connected to a terminal 473.

The receiver 430 receives the base clock signal CK via a signal line connected to a terminal 474. The base clock signal CK is set to be valid or invalid in accordance with the clock-enable signal EN, and supplied to each of circuits included in the memory-side interface circuit 410.

The strobe transmission unit 435 transmits a strobe signal DQS to the memory controller 300 in synchronization with the base clock signal CK via a strobe line connected to a terminal 475. The data transmission unit 440 transmits data DQ obtained by dividing read data by a unit of transmission to the memory controller 300 in synchronization with the base clock signal CK via a data line connected to a terminal 476. Due to the strobe transmission unit 435 and the data transmission unit 440, the data DQ and the strobe signal DQS are transmitted in synchronization. Note that the data DQ is an example of the unit data described in the claims.

The data reception unit 450 receives the data DQ in synchronization with the base clock signal CK via a data line connected to the terminal 476.

The data transmission unit 460 has a similar configuration to the data transmission unit 440 except that data is transmitted via a data line connected to a terminal 477. The data reception unit 461 has a similar configuration to the data reception unit 450 except that data is received via another data line connected to the terminal 477.

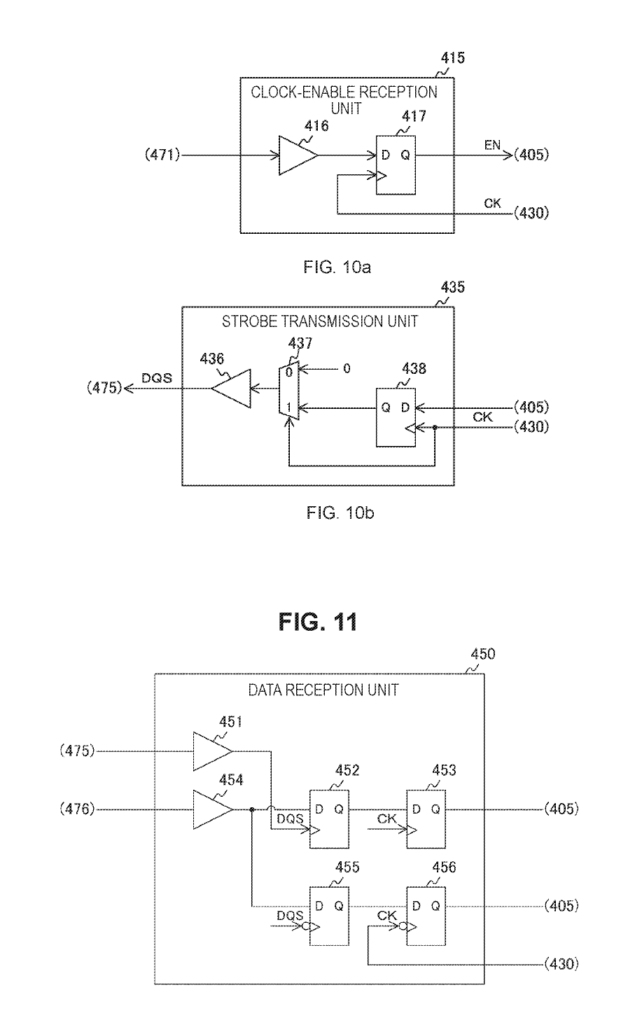

FIG. 10 is a circuit diagram illustrating configuration examples of the clock-enable reception unit 415 and the strobe transmission unit 435 according to the first embodiment. a of the diagram is a circuit diagram illustrating a configuration example of the clock-enable reception unit 415. b of the diagram is a circuit diagram illustrating a configuration example of the strobe transmission unit 435.

The clock-enable reception unit 415 includes a receiver 416 and a flip-flop 417. The receiver 416 receives a clock-enable signal EN and supplies the signal to the flip-flop 417. The flip-flop 417 holds the clock-enable signal in synchronization with the base clock signal CK, and outputs the signal to a bus 405.

Note that configurations of the chip-select reception unit 420 and the command/address reception unit 425 are similar to that of the clock-enable reception unit 415.

The strobe transmission unit 435 includes a driver 436, a selector 437, and a flip-flop 438. The driver 436 adds a preamble signal and a postamble signal to the head and the tail of the strobe signal DQS and sequentially transmits the signals to the memory controller 300. The selector 437 switches a signal from the flip-flop 437 and “0” in accordance with the base clock signal CK and transmits the result to the driver 436. The flip-flop 437 holds the strobe signal DQS issued by the memory control unit 480 in synchronization with the base clock signal CK and outputs the signal to the selector 436.

Note that configurations of the data transmission units 440 and 460 are similar to that of the strobe transmission unit 435.

### [Configuration Example of Data Reception Unit]

FIG. 11 is a circuit diagram illustrating a configuration example of the data reception unit 450 according to the first embodiment. The data reception unit 450 includes receivers 451 and 454, and flip-flops 452, 453, 455, and 456.

The receiver 451 receives a strobe signal DQS via the strobe line. The receiver 454 receives data DQ and supplies the data to the flip-flops 452 and 455.

The flip-flop 452 holds the data DQ from the memory controller 300 in synchronization with the strobe signal DQS, and supplies the data to the flip-flop 453. The flip-flop 453 holds the data DQ in synchronization with a base clock signal CK, and outputs the data to the bus 405. The flip-flops 452 and 453 hold data transferred in synchronization with a rise of the strobe signal.

The flip-flop 455 holds the data DQ from the memory controller 300 in synchronization with an inverted strobe signal DQS and supplies the data to the flip-flop 456. The flip-flop 456 holds the data DQ in synchronization with an inverted base clock signal CK and outputs the data to the bus 405. The flip-flops 455 and 456 hold data transferred in synchronization with a fall of the strobe signal.

### [Configuration Example of Memory Control Unit]

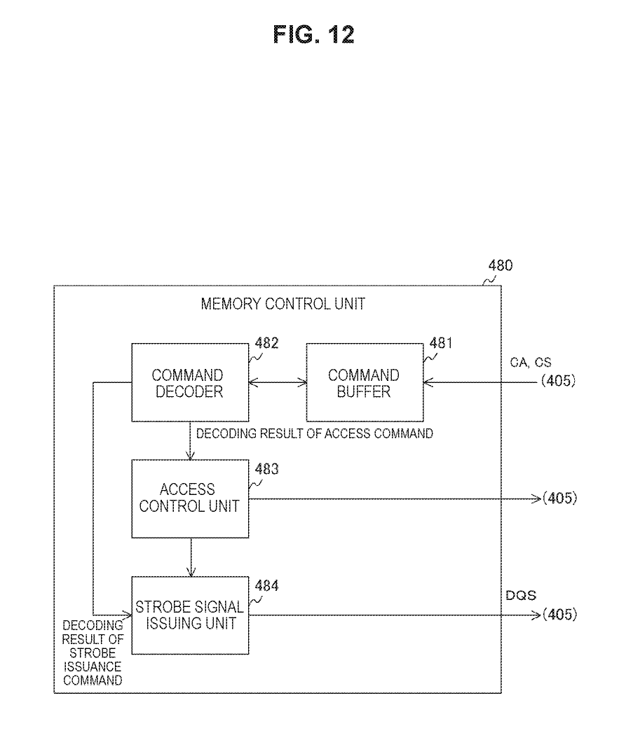

FIG. 12 is a block diagram illustrating a configuration example of the memory control unit 480 according to the first embodiment. The memory control unit 480 includes a command buffer 481, a command decoder 482, an access control unit 483, and a strobe signal issuing unit 484.

The command buffer 481 holds commands in order of their reception. The command decoder 482 decodes the commands. The command decoder 482 reads each unprocessed command from the command buffer 481 and decodes the command, and deletes the decoded command from the command buffer 481. In addition, the command decoder 482 supplies a decoding result of an access command to the access control unit 483, and supplies a decoding result of a strobe issuance command to the strobe signal issuing unit 484.

The access control unit 483 controls the driver 403 and the address decoder 404 on the basis of the decoding result of the access command to perform writing and reading of data. In addition, the access control unit 483 supplies information (a data size of read data, or the like) necessary for acquiring the number of issuance operations of a strobe signal to the strobe signal issuing unit 484.

The strobe signal issuing unit 484 issues a strobe signal. The strobe signal issuing unit 484 acquires the number of pieces of data DQ obtained by dividing read data by a unit of transmission on the basis of the information from the access control unit, and issues a strobe signal having the same number of cycles as the number of pieces of the data. In addition, the strobe signal issuing unit 484 issues the strobe signal having the number of cycles E in accordance with the decoding result of the strobe issuance command. The issued strobe signal is supplied to the memory-side interface circuit 410 via the bus 405.

### [Operation Example of Stroage]

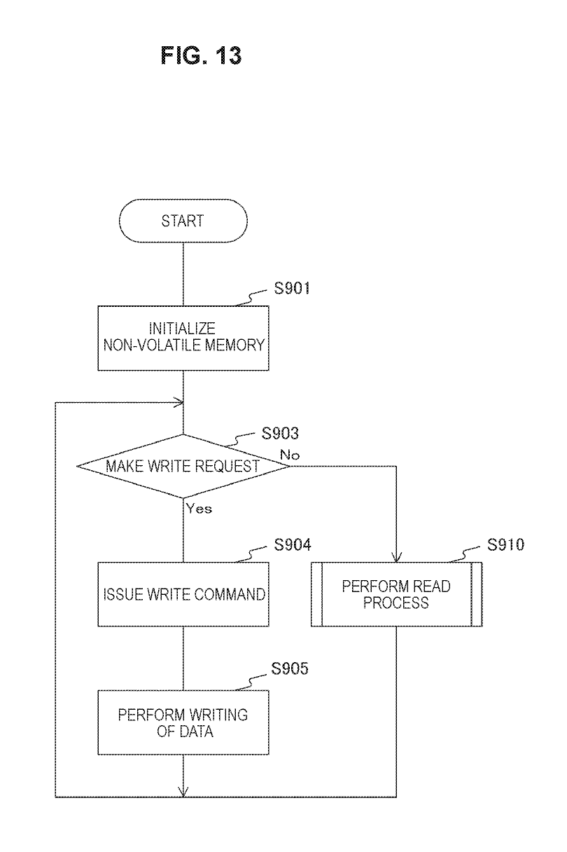

FIG. 13 is a flowchart showing an example of an operation of the storage 200 according to the first embodiment. The operation starts when, for example, power is input to the storage 200.

The memory controller 300 performs initialization of the non-volatile memory 400 (Step S901), and determines whether or not writing of data has been requested with a write request (Step S903). When writing of data has been requested (Yes in Step S903), the memory controller 300 issues a write command (Step S904), and the non-volatile memory 400 performs writing of data in accordance with the write command (Step S905).

On the other hand, when reading of data has been requested with a read request (No in Step S903), the storage 200 performs a read process (Step S910). After Step 5905 or 5910, the storage 200 returns to Step 5903.

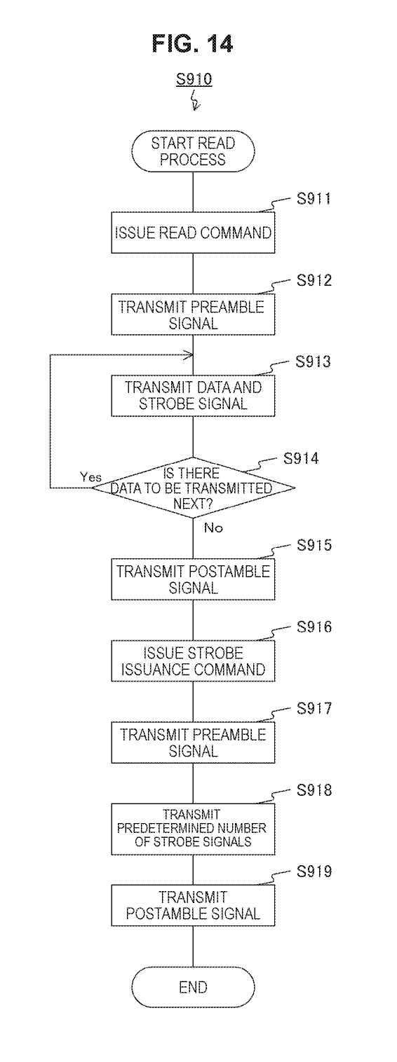

FIG. 14 is a flowchart showing an example of a read process according to the first embodiment. The memory controller 300 issues a read command in accordance with a read request (Step S911). The non-volatile memory 400 reads data in accordance with the read command, and transmits a preamble signal (Step S912). Then, the non-volatile memory 400 synchronizes the data with a strobe signal, and then transmits the data and the signal (Step S913).

The non-volatile memory 400 determines whether or not there is data to be transmitted next (Step S914). When there is data to be transmitted next (Yes in Step S914), the non-volatile memory 400 returns to Step 5913. On the other hand, when there is no data to be transmitted next (No in Step S914), the non-volatile memory 400 transmits a postamble signal (Step S915).

The memory controller 300 that has received the postamble signal issues a strobe issuance command (Step S916). The non-volatile memory 400 transmits a preamble signal (Step S917), then transmits a strobe signal having the number of cycles E without accompanying valid data (Step S918), and then transmits a postamble signal (Step S919). After Step 5919, the storage 200 ends the read process.

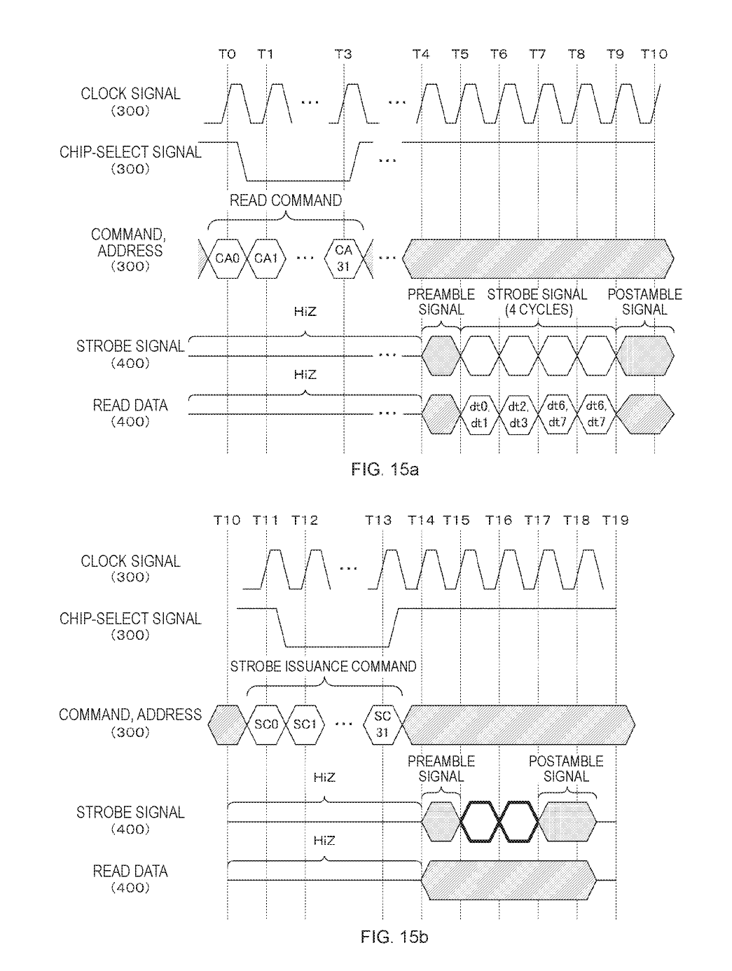

FIG. 15 shows timing charts of examples of timings at which the memory controller 300 transmits and receives signals according to the first embodiment. a of the diagram is a timing chart for timings T0 to T10, and b of the diagram is a timing chart for timings after timing T10. First, the memory controller 300 sets a chip-select signal to a low level (valid) at the timing T0, and issues a read command in accordance with a read request. After the issuance of the read command, the chip-select signal is set to a high level (invalid).

The non-volatile memory 400 reads read data in accordance with the read command, and transmits a preamble signal via a strobe line at the timing T4. Then, the non-volatile memory 400 synchronizes 4 pieces of valid data with a strobe signal having 4 cycles and transmits the data and the signal at timings T5 to T9, and transmits a postamble signal at the timing T10. The data includes data transferred at rises and data transferred at falls of the strobe signal. The 4 pieces of data include, for example, 8 pieces of data dt0 to dt7. When the data is transferred in parallel on 8 data lines, for example, a data size of each piece of dt0 to dt7 is 8 bits. In addition, dt0, dt2, dt6, and dt8 are transferred in synchronization with rises of the strobe signal, and the remaining data is transferred in synchronization with falls thereof. Thus, the data is transferred in units of 16 bits in synchronization with the strobe signal.

The memory controller 300 that has received the postamble signal issues a strobe issuance command by setting the chip-select signal to a low level at the timing T11. The non-volatile memory 400 transmits a preamble signal in accordance with the strobe issuance command at the timing T14, and transmits a strobe signal having 2 cycles at the timings T15 and T16. Then, the non-volatile memory 400 transmits a postamble signal at the timing T17. Note that the hatched line portions of FIG. 15 indicate invalid data. In addition, “HiZ” indicates a high impedance state.

As described above, the non-volatile memory 400 transmits a strobe signal having a greater number of cycles than the number of pieces of valid data to the memory controller 300.

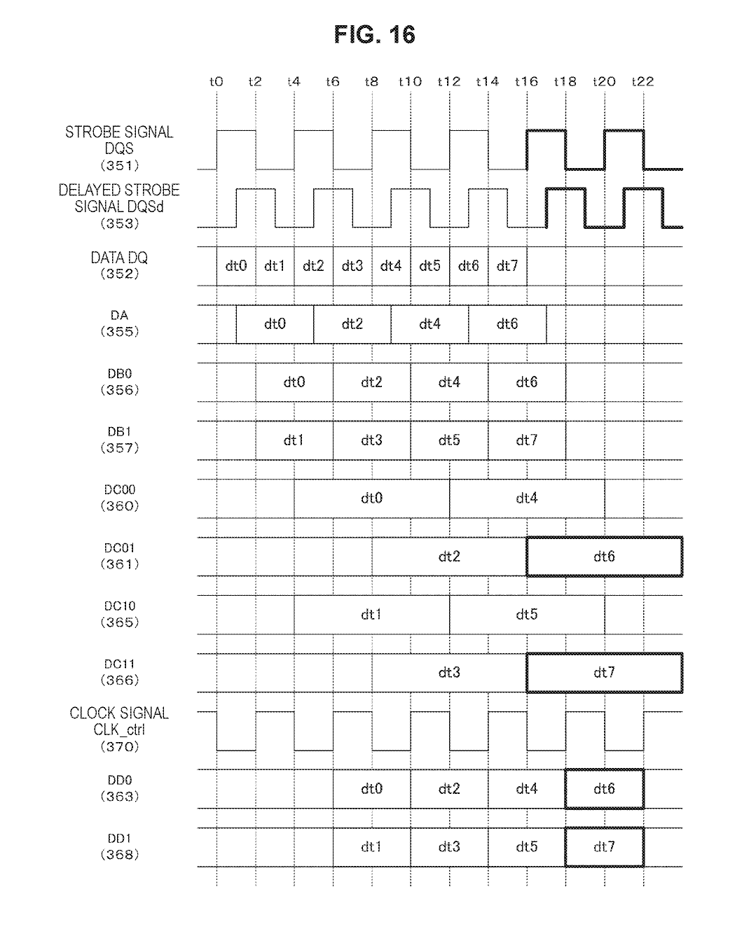

FIG. 16 is a timing chart illustrating an example of timings at which the memory controller 300 and the non-volatile memory 400 transmit and receive signals according to the first embodiment. For example, 8 pieces of data from dt0 to dt7 are sequentially transmitted in synchronization with a strobe signal DQS.

The flip-flop 355 sequentially holds the data dt0, dt2, dt4, and dt6 at timings t2, t6, t10, and t14. Then, the flip-flop 356 in the later stage sequentially holds the data dt0, dt2, dt4, and dt6 from the flip-flop 356 at timings t4, t8, t12, and t16. On the other hand, the flip-flop 357 sequentially holds the data dtl, dt3, dt5, and dt7 at the timings t4, t8, t12, and t16.

The flip-flop 360 in the later stage of the flip-flop 356 sequentially holds the data dt0 and dt4 at the timings t6 and t14. On the other hand, the flip-flop 361 holds the data dt2 at the timing t12.

Transmission of the strobe signal having 4 cycles is completed at the timing T16. At this point, the final data dt6 among the data dt0, dt2, dt4, and dt6 is not held in the flip-flop 361 of the final stage. The non-volatile memory 400, however, transmits an extra strobe signal at the timings t16 and t20. The final data dt6 is extracted at the timing t20 due to the strobe signal, and then held in the flip-flop 361 of the final stage. Thus, all of the data dt0, dt2, dt4, and dt6 is sequentially output to the flip-flop 363 of the later stage.

In addition, the flip-flop 365 in the later stage of the flip-flop 357 sequentially holds the data dtl and dt5 at the timings t6 and t14. Meanwhile, the flip-flop 366 holds the data dt3 at the timing t12. The final data dt7 among the data dtl, dt3, dt5, and dt7 is not held in the flip-flop 366 of the final stage at the timing T16 at which the transmission of the strobe signal having 4 cycles is completed. However, since the non-volatile memory 400 transmits an extra strobe signal at the timings t16 and t20, the final data dt7 is extracted and held in the flip-flop 361 of the final stage at the timing t20. Thus, all of the data dtl, dt3, dt5, and dt7 is sequentially output to the flip-flop 368 of the later stage.

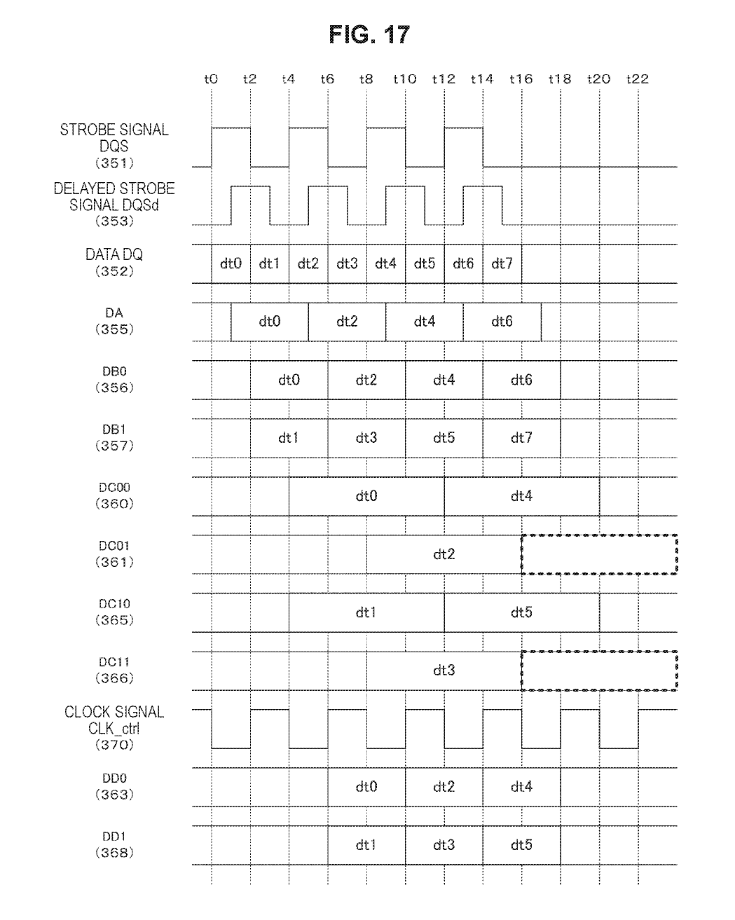

FIG. 17 is a timing chart illustrating an example of timings at which the memory controller holds data according to a comparative example of the first embodiment. In this comparative example, it is assumed that a strobe signal having the same number of cycles as the number of pieces of valid data is transmitted by the non-volatile memory 400. In this case, the final data dt6 is not held in the flip-flop 361 at a timing T16 at which transmission of the strobe signal having 4 cycles has been completed, but stays in the flip-flop 356 of the previous stage. In addition, the final data dt7 is not held in the flip-flop 365 either, but stays in the flip-flop 357 of the previous stage. Thus, the final data dt6 and dt7 is not output to the flip-flops 363 and 368 of the later stages, and the memory controller 300 is not able to take out all of the data in synchronization with a clock signal.

On the other hand, all data is output from the flip-flop of the final stage in a configuration in which the non-volatile memory 400 issues a strobe signal having a greater number of cycles than the number of pieces of the data, as illustrated in FIG. 16. Thus, the memory controller 300 can take out all of the data in synchronization with a clock signal. According to the configuration, a phase adjustment circuit may not be provided, unlike in Patent Literature 1, and thus component costs, design costs, and the like can be reduced accordingly.

As described above, according to the first embodiment of the present technology, the non-volatile memory 400 synchronizes a strobe signal having a greater number of cycles than the number of pieces of data with the data and transmits the signal and the data, and thus the memory controller 300 can cause all of the data to be held in the holding units of the plurality of stages and take out the data.

### [Modified Example]

Although the memory controller 300 and the non-volatile memory 400 transfer data in the DDR scheme in the first embodiment, the memory controller and the non-volatile memory may transfer data in a single data rate (SDR) scheme. A memory controller 300 and a non-volatile memory 400 of a modified example of the first embodiment are different from those of the first embodiment in terms of transferring data in the SDR scheme.

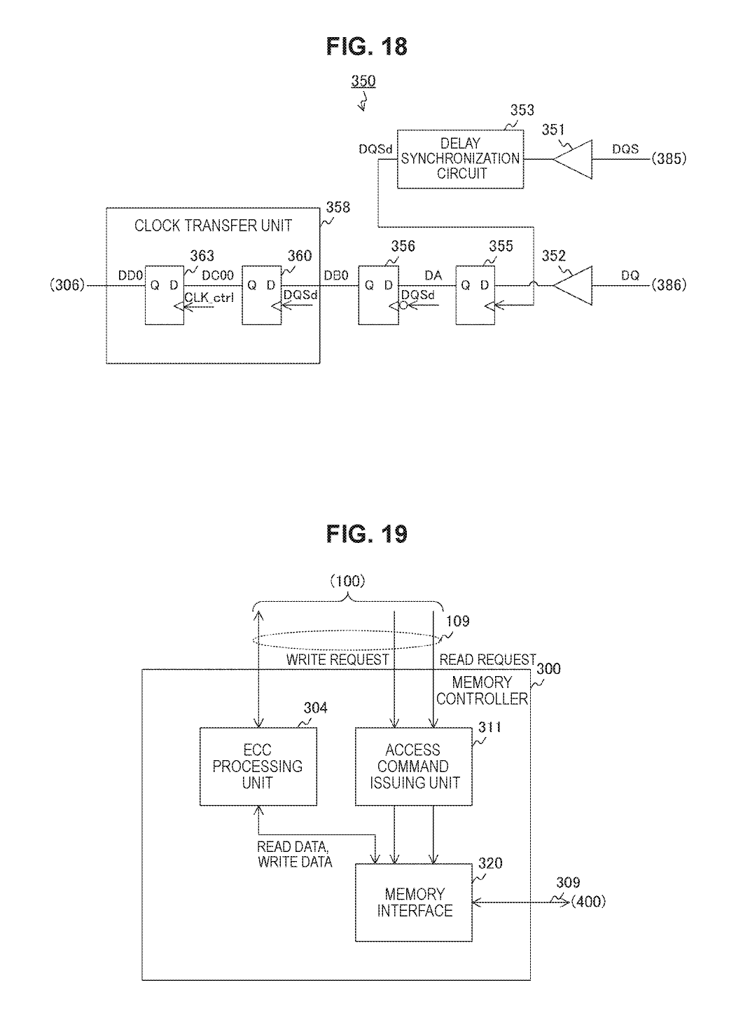

FIG. 18 is a block diagram illustrating a configuration example of a data reception unit 350 according to the modified example of the first embodiment. The data reception unit 350 according to the modified example is different from that of the first embodiment in that flip-flops 355 and 356 are provided instead of the serial/parallel conversion unit 354. In addition, a clock transfer unit 358 according to the modified example is different from that of the first embodiment in that only flip-flops 360 and 363 are provided.

The flip-flop 360 is provided in the later stage of the flip-flop 356, and the flip-flop 363 is provided in the later stage of the flip-flop 360. The flip-flops hold data in synchronization with rises of a strobe signal.

As described above, according to the modified example, since the non-volatile memory 400 transmits data in synchronization with rises of the strobe signal having a greater number of cycles than the number of pieces of data, data can be transmitted and received in a simpler circuit configuration than when data is transmitted in synchronization with rises and falls.

### 2. Second Embodiment

Although the non-volatile memory 400 issues an extra strobe signal in accordance with a strobe issuance command in the first embodiment, an extra strobe signal may be issued without receiving a strobe issuance command. A non-volatile memory 400 of a second embodiment is different from that of the first embodiment in that the former receives no strobe issuance command.

FIG. 19 is a block diagram illustrating a functional configuration example of a memory controller 300 according to the second embodiment. The memory controller 300 of the second embodiment is different from that of the first embodiment in that the former does not include the strobe issuance instructing unit 312.

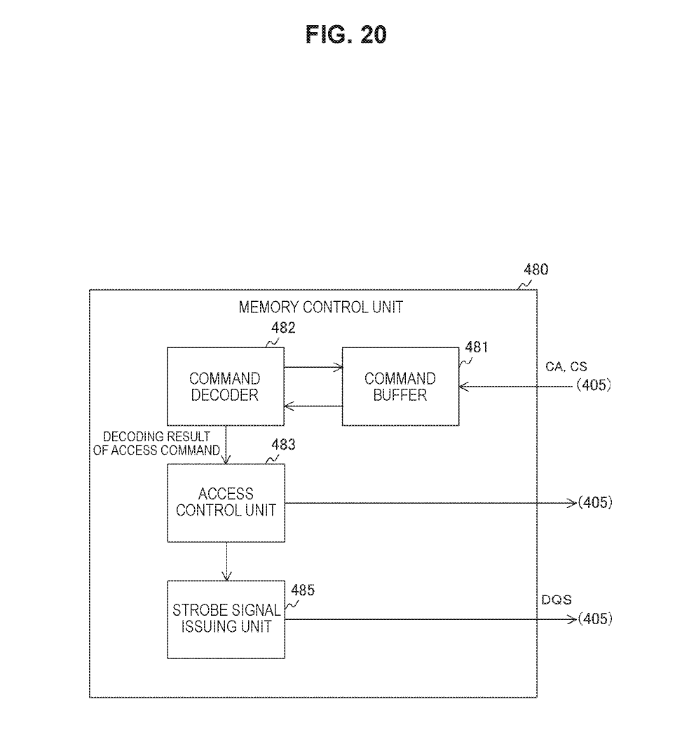

FIG. 20 is a block diagram illustrating a configuration example of a memory control unit 480 according to the second embodiment. The memory control unit 480 of the second embodiment is different from that of the first embodiment in that the former includes a strobe signal issuing unit 485 instead of the strobe signal issuing unit 484.

The strobe signal issuing unit 485 generates a strobe signal having a greater number of cycles than the number of pieces of data on the basis of information from an access control unit 483. When the number of cycles of an extra strobe signal issued is set to “2” and the number of pieces of data is set to “4,” for example, a strobe signal having 6 cycles is issued.

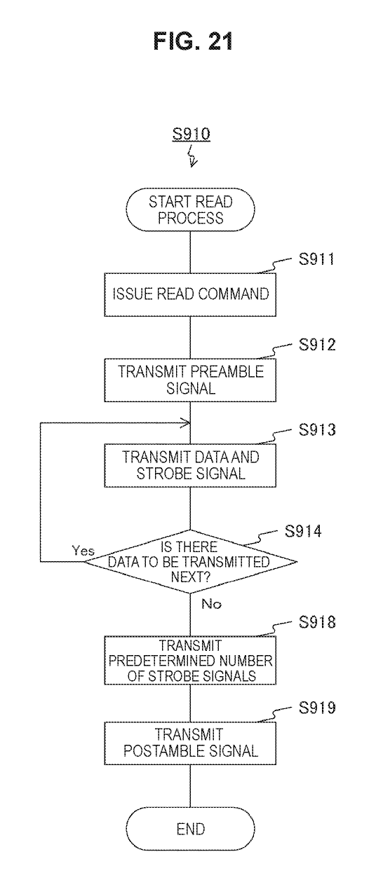

FIG. 21 is a flowchart showing an example of a read process according to the second embodiment. The read process of the second embodiment is different from that of the first embodiment in that Steps S915 to S917 are not executed.

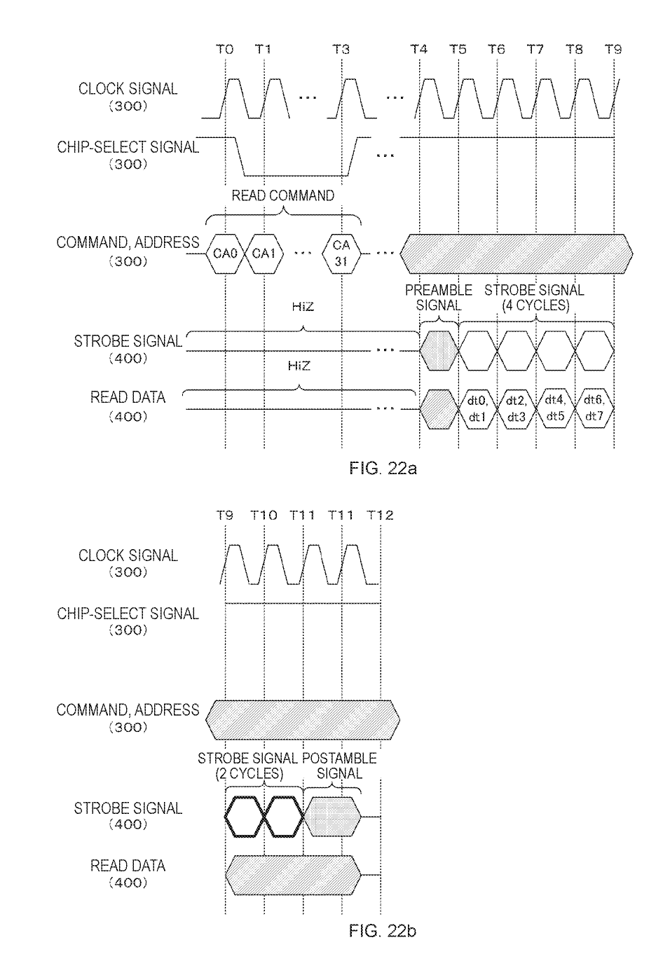

FIG. 22 shows timing charts of examples of timings at which the memory controller 300 and the non-volatile memory 400 transmit and receive signals according to the second embodiment. a of the diagram is a timing chart of timings T0 to T9, and b of the diagram is a timing chart of timings from the timing T9. First, the memory controller 300 issues a read command in accordance with a read request at the timing T0.

The non-volatile memory 400 reads read data in accordance with the read command, and transmits a preamble signal at the timing T4. Then, the non-volatile memory 400 synchronizes 4 pieces of valid data with a strobe signal having 4 cycles and transmits the data and the signal at the timings T5 to T8.

Then, the non-volatile memory 400 transmits invalid data and a strobe signal having 2 cycles at the timings T9 and T10, and then transmits a postamble signal at the timing T11.

As described above, according to the second embodiment, since the non-volatile memory 400 transmits a strobe signal having the same number of cycles as the number of pieces of data and the data, and then transmits a strobe signal having the number of cycles E, it is not necessary to issue a strobe issuance command.

### [Modified Example]

Although the non-volatile memory 400 transmits the strobe signal having the number of cycles E after transmitting all data in the second embodiment, the non-volatile memory may transmit an extra strobe signal within a non-transmission period in which transmission of read data is halted. A non-volatile memory 400 of a modified example of the second embodiment is different from that of the second embodiment in that an extra strobe signal is transmitted within a non-transmission period.

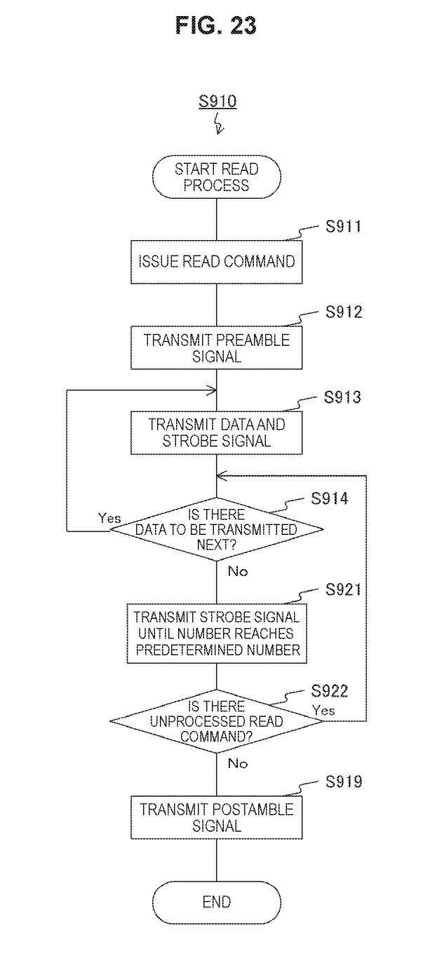

FIG. 23 is a flowchart showing an example of a read process according to the modified example of the second embodiment. The read process of the modified example is different from the second embodiment in that Steps S921 and S922 are further executed.

When there is no data to be transmitted next (No in Step S914), the non-volatile memory 400 repeatedly transmits the strobe signal until its number of cycles reaches a predetermined number E (e.g., “2”) (Step S921). Then, the non-volatile memory 400 determines whether or not there is an unprocessed read command in the command buffer 481 (Step S922). When there is an unprocessed read command (Yes in Step S922), the non-volatile memory 400 returns to Step S914.

On the other hand, when there is no unprocessed read command (No in Step S922), the non-volatile memory 400 determines that transfer of all data is completed, and transmits a postamble signal (Step S919).

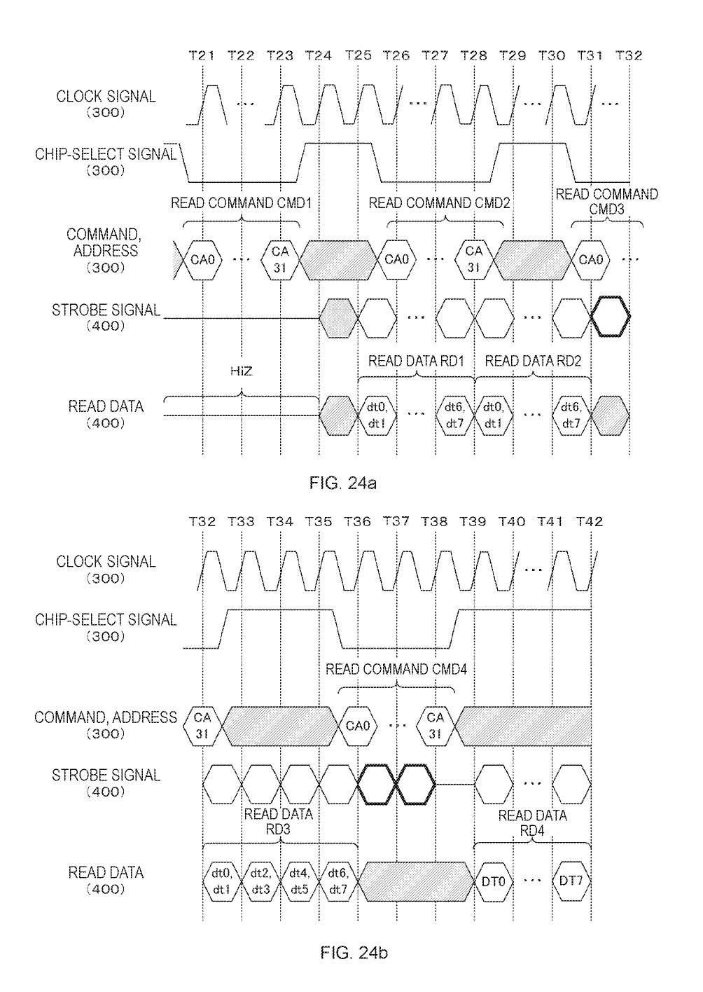

FIG. 24 shows timing charts of examples of timings at which a memory controller 300 and the non-volatile memory 400 transmit and receive signals according to the modified example of the second embodiment. a of the diagram is a timing chart of timings T21 to T32, and b of the diagram is a timing chart from the timing T32. The memory controller 300 issues a read command CMD1 in accordance with a read request at the timing T21.

The non-volatile memory 400 reads read data RD1 in accordance with the read command CMD1, and transmits a preamble signal at the timing T24. Then, the non-volatile memory 400 synchronizes the read data RD1 with a strobe signal and transmits the data and the signal at the timings T25 to T27.

Meanwhile, the memory controller 300 issues a read command CMD2 at the timing T26. The non-volatile memory 400 reads read data RD2 in accordance with the read command CMD2, and synchronizes the read data RD2 with the strobe signal and transmits the data and the signal at the timings T28 to T30.

In addition, the memory controller 300 issues a read command CMD3 at the timing T31. Since decoding of the read command CMD3 has not been completed at the timing T31, transmission of data is intermitted. In this data non-transmission period, the non-volatile memory 400 transmits invalid data and a strobe signal. Then, the non-volatile memory 400 reads read data RD3 in accordance with the read command CMD3, and synchronizes the read data RD3 with the strobe signal and transmits the data and the signal at the timings T32 to T35.

Then, the memory controller 300 issues a read command CMD4 at the timing T36. Data corresponding to the read command CMD4 is not read, but transmission of the data is intermitted in the period of timings T36 to T39. In this data non-transmission period, the non-volatile memory 400 repeatedly transmits the strobe signal until its number of cycles reaches 2. Then, the non-volatile memory 400 reads read data RD4 in accordance with the read command CMD4, and synchronizes the read data RD4 with the strobe signal and transmits the data and the signal at the timings T39 to T41.

As described above, according to the modified example, since the non-volatile memory 400 transmits the strobe signal in the data non-transmission period, a decrease in a data transmission speed can be suppressed.

### 3. Third Embodiment

In the first embodiment, the non-volatile memory 400 has the number of cycles E of an extra strobe signal to be issued set to be a fixed value, however, the number of cycles may be changed under control of the memory controller 300. The necessary number of extra cycles E can be obtained from the number of stages of flip-flops when the memory controller 300 is practically mounted, however, when some circuits are provided from another company or a design thereof has been modified, for example, it is necessary to change the value of the number of cycles E. A non-volatile memory 400 of a third embodiment is different from that of the first embodiment in that a value of the number of cycles E is changed in accordance with control of a memory controller.

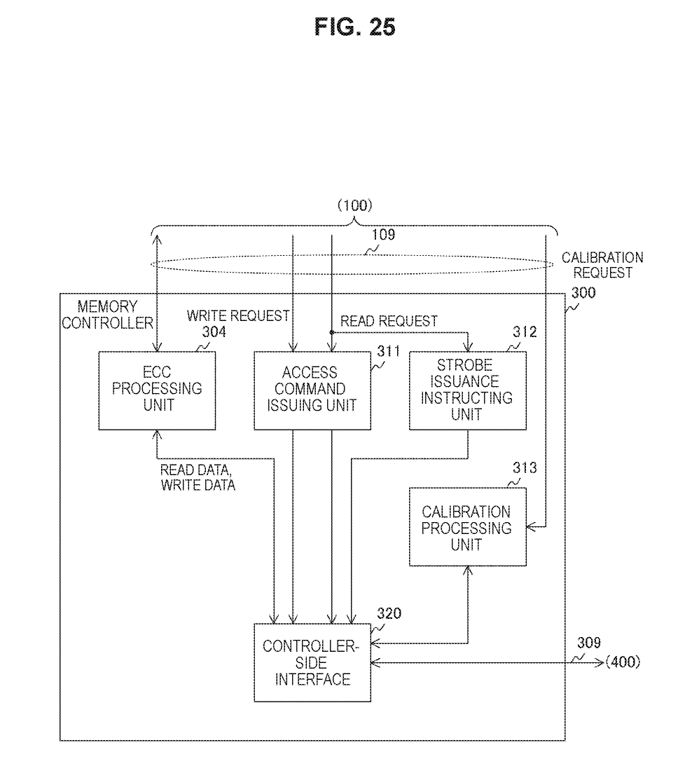

FIG. 25 is a block diagram illustrating a functional configuration example of a memory controller 300 according to the third embodiment. The memory controller 300 of the third embodiment is different from that of the first embodiment in that a calibration processing unit 313 is further included.

The calibration processing unit 313 performs a calibration process of adjusting impedance, a timing, and the like of a data line in accordance with a calibration request from a host computer 100. In the calibration process, the calibration processing unit 313 issues a calibration command for requesting an output of specific pattern data for performing calibration. For example, a mode register read (MRR) command based on the low power double data rate (LPDDR) 2 standard is issued as a calibration command. In addition, the calibration command includes description of the number of cycles of an extra strobe signal to be issued. Thus, the memory controller 300 can set the number of extra cycles E to be issued using the calibration command. A minimum value that can be set for E is “0.” Note that the calibration command is an example of the setting command described in the claims.

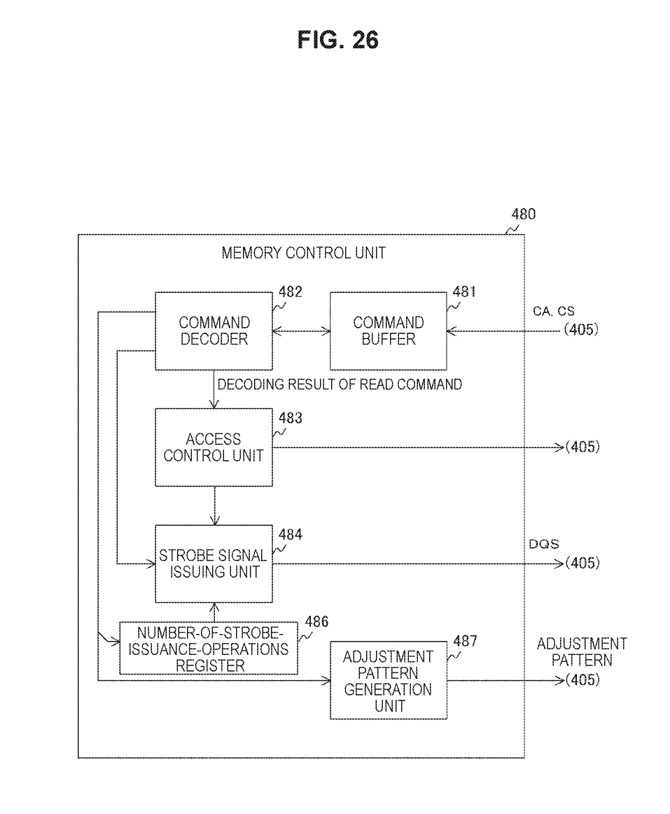

FIG. 26 is a block diagram illustrating a configuration example of a memory control unit 480 according to the third embodiment. The memory control unit 480 of the third embodiment is different from that of the first embodiment in that a number-of-strobe-issuance-operations register 486 and an adjustment pattern generation unit 487 are further provided.

The number-of-strobe-issuance-operations register 486 holds a set number of cycles E. The number-of-strobe-issuance-operations register 486 holds the number of cycles E elicited through decoding of a calibration command. The held value is valid until the non-volatile memory 400 is re-activated and initialized. A strobe signal issuing unit 484 of the third embodiment reads the number of cycles E held in the number-of-strobe-issuance-operations register 486, and issues an extra strobe signal having the number of cycles.

When a phase adjustment circuit is practically mounted in the memory controller 300 as described in Patent Literature 1, a strobe signal having the same number of cycles as the number of pieces of data should be issued, and thus “0” is set in the number-of-strobe-issuance-operations register 486. On the other hand, when no phase adjustment circuit is mounted in the memory controller 300, a given value higher than “0” is set in the number-of-strobe-issuance-operations register 486. By configuring the number of cycles E held in the number-of-strobe-issuance-operations register 486 to be changeable as described above, selection options in designing the memory controller 300 can increase.

In addition, by setting the number of cycles E at the time of calibration, a storage 200 can perform an activation process in the same procedure as in the related art.

Note that, although a value of the number-of-strobe-issuance-operations register 486 is changed using a calibration command, a configuration in which such registration is updated using a command other than a calibration command can also be adopted.

The adjustment pattern generation unit 487 generates pattern data for calibration as an adjustment pattern in accordance with a calibration command.

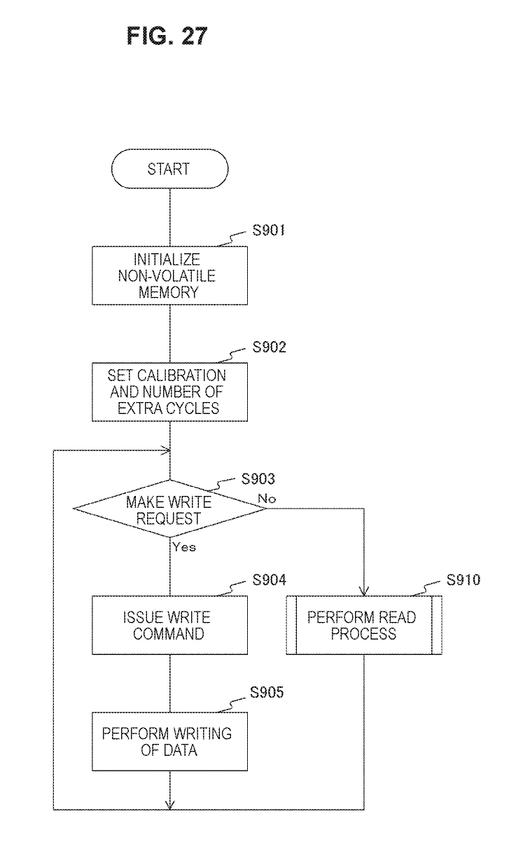

FIG. 27 is a flowchart showing an example of an operation of the storage 200 according to the third embodiment. The operation of the storage 200 of the third embodiment is different from that of the first embodiment in that Step S902 is further executed.

After initialization of the non-volatile memory 400 (Step S901), the memory controller 300 sets the number of cycles of an extra strobe signal to be issued along with calibration (Step S902). Then, the storage 200 performs the processes from Step S903.

As described above, according to the third embodiment, the memory controller 300 sets the number of cycles of an extra strobe signal to be issued using a calibration command, and thus the number of cycles of the extra strobe signal can be changed to an arbitrary value.

### 4. Fourth Embodiment

In the first embodiment, the number of cycles E of an extra strobe signal to be issued is set to a fixed value, however, the number of cycles E may be obtained through transmission and reception of existing pattern data. The necessary number of extra cycles can be obtained from the number of stages of flip-flops when the memory controller 300 is practically mounted, however, when some circuits are provided from another company or a design thereof has been modified, for example, it is necessary to check the necessary number of cycles. A non-volatile memory 400 of a fourth embodiment is different from that of the first embodiment in that the number of extra cycles E to be issued is obtained through transmission and reception of pattern data.

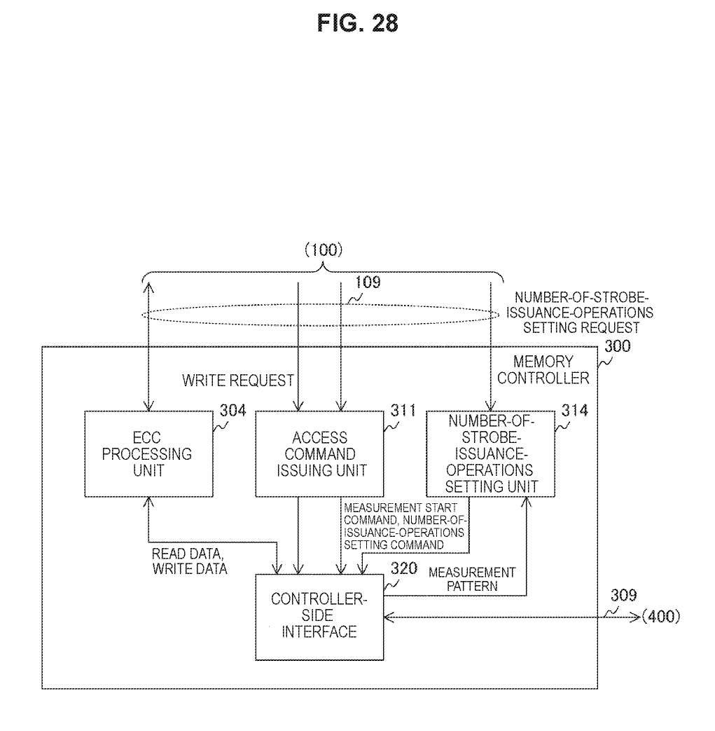

FIG. 28 is a block diagram illustrating a functional configuration example of a memory controller 300 according to the fourth embodiment. The memory controller 300 of the fourth embodiment is different from that of the first embodiment in that a number-of-strobe-issuance-operations setting unit 314 is further included.

The number-of-strobe-issuance-operations setting unit 314 computes and sets the necessary number of extra cycles of a strobe signal. The number-of-strobe-issuance-operations setting unit 314 issues a measurement start command in accordance with a number-of-strobe-issuance-operations setting request from a host computer 100. The measurement start command is a command for instructing the non-volatile memory 400 to transmit existing pattern data as a measurement pattern.

The non-volatile memory 400 synchronizes s pieces of data DQ obtained by dividing the measurement pattern by a transmission unit with a strobe signal and transmits the data and the signal in accordance with the measurement start command. A controller-side interface circuit 320 receives the data DQ obtained by dividing the measurement pattern in synchronization with the strobe signal. The number-of-strobe-issuance-operations setting unit 314 computes the difference between the number of pieces r of the received data DQ and s as a necessary number of cycles. When, for example, the number of pieces s of the transmitted data DQ is “10” and the number of received pieces r is “8,” “2” is computed as the necessary number of cycles E. Then, the number-of-strobe-issuance-operations setting unit 314 issues and transmits a number-of-issuance-operations setting command for setting the computed number of cycles E.

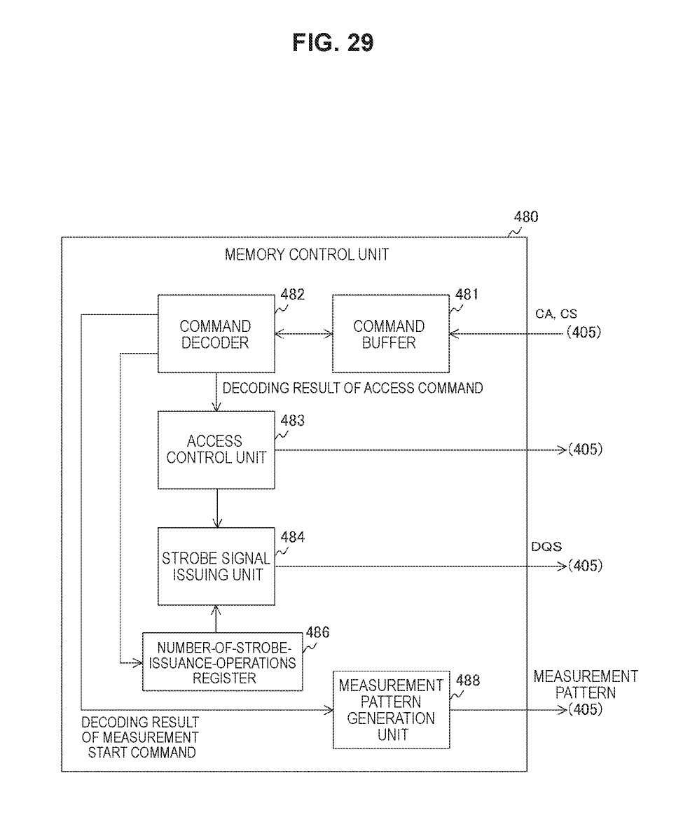

FIG. 29 is a block diagram illustrating a configuration example of a memory control unit 480 according to the fourth embodiment. The memory control unit 480 of the fourth embodiment is different from that of the first embodiment in that a number-of-strobe-issuance-operations register 486 and a measurement pattern generation unit 488 are further included. In addition, the number-of-strobe-issuance-operations register 486 holds the number of cycles obtained through decoding of a number-of-issuance-operations setting command.

The measurement pattern generation unit 488 generates a measurement pattern on the basis of a decoding result of a measurement start command, and supplies the pattern to a memory-side interface circuit 410 via a bus 405.

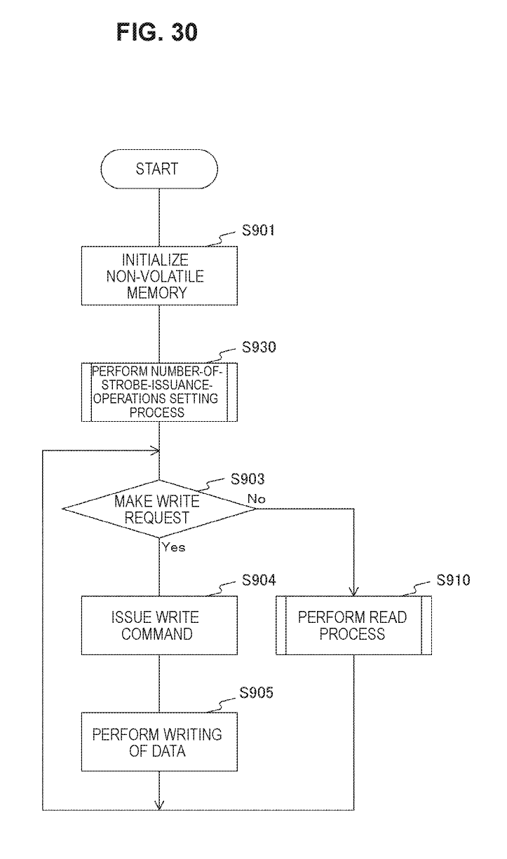

FIG. 30 is a flowchart showing an example of an operation of a storage 200 according to the fourth embodiment. The operation of the storage 200 of the fourth embodiment is different from that of the first embodiment in that, after initialization of the non-volatile memory 400 (Step S901), a number-of-strobe-issuance-operations setting process (Step S930) is executed.

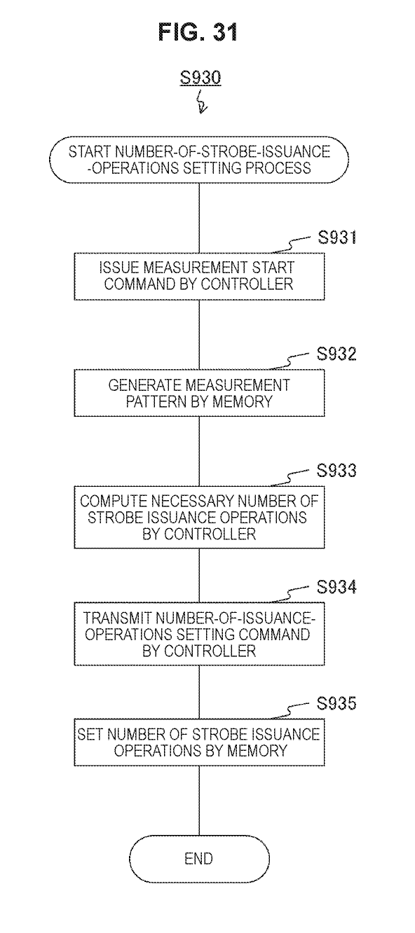

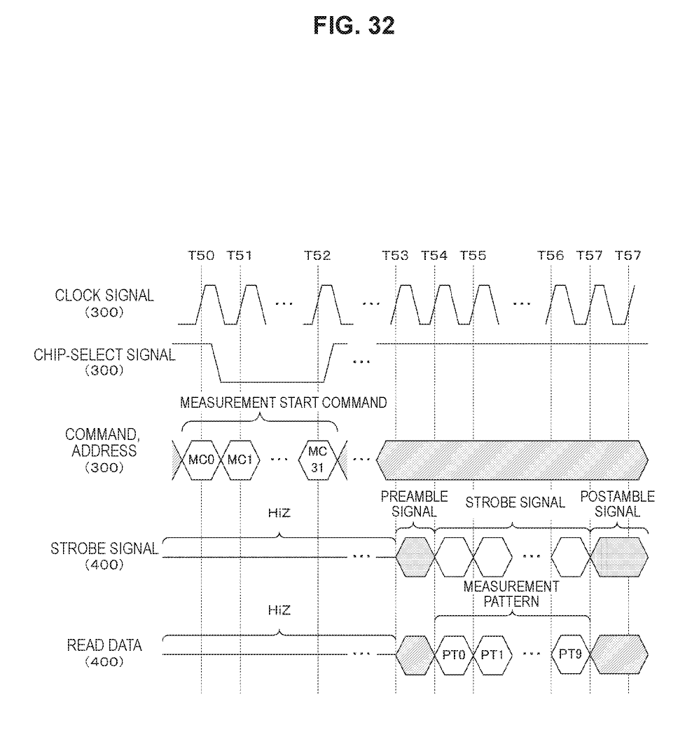

FIG. 31 is a flowchart showing an example of the number-of-strobe-issuance-operations setting process according to the fourth embodiment. The memory controller 300 issues and transmits a measurement start command in accordance with a number-of-strobe-issuance-operations setting request (Step S931). The non-volatile memory 400 generates a measurement pattern in accordance with the measurement start command, and divides the pattern by a unit of transmission and transmits the data (Step S932). The memory controller 300 receives the data from the non-volatile memory 400, and computes the necessary number of issuance operations E of a strobe signal on the basis of the number of pieces s transmitted from the non-volatile memory 400 and the number of pieces r received by the memory controller 300 (Step S933).

The memory controller 300 issues and transmits a number-of-issuance-operations setting command for setting the computed number of pieces (Step S934), and the non-volatile memory 400 sets the number of extra cycles E to be issued in accordance with the number-of-issuance-operations setting command (Step S935).

FIG. 32 is a timing chart showing an example of timings at which the memory controller 300 and the non-volatile memory 400 transmit and receive signals according to the fourth embodiment. When the memory controller 300 transmits a measurement start command at a timing T50, the non-volatile memory 400 generates a measurement pattern in accordance with the measurement start command. The non-volatile memory 400 transmits a preamble signal at a timing T53, and transmits data PT0 to PT9 obtained by dividing the measurement pattern in synchronization with a strobe signal at timings T54 to T56. Then, the non-volatile memory 400 transmits a postamble signal at a timing T57. The memory controller 300 sets the difference between the number of received pieces r from PT0 to PT9 and the number of transmitted pieces as a necessary number of cycles E.

As described above, according to the fourth embodiment, the memory controller 300 sets the difference between the number of transmitted pieces and the number of received pieces of data obtained by dividing the measurement pattern as the number of cycles of the strobe signal, and thus the number of necessary cycles of the strobe signal can be accurately obtained and set.

The above-described embodiments are examples for embodying the present technology, and matters in the embodiments each have a corresponding relationship with disclosure-specific matters in the claims. Likewise, the matters in the embodiments and the disclosure-specific matters in the claims denoted by the same names have a corresponding relationship with each other. However, the present technology is not limited to the embodiments, and various modifications of the embodiments may be embodied in the scope of the present technology without departing from the spirit of the present technology.

The processing sequences that are described in the embodiments described above may be handled as a method having a series of sequences or may be handled as a program for causing a computer to execute the series of sequences and recording medium storing the program. As the recording medium, a CD (Compact Disc), an MD (MiniDisc), and a DVD (Digital Versatile Disc), a memory card, and a Blu-ray disc (registered trademark) can be used.

Note that the effects described here are not necessarily limited, and any effect that is desired to be described in the present disclosure may be exhibited.

Additionally, the present technology may also be configured as below.
(1)

An interface circuit including:

a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and

a controller-side interface circuit configured to sequentially hold the transmitted unit data in holding units of a plurality of stages in synchronization with the first periodic signal and to sequentially read and output the held unit data in synchronization with a second periodic signal.
(2)

The interface circuit according to (1),

wherein the controller-side interface circuit transmits a read command for instructing reading of the read data to the memory-side interface circuit,

the memory-side interface circuit reads the read data in accordance with the read command, synchronizes the unit data with the first periodic signal having the same number of cycles as the number of pieces of the unit data, and sequentially transmits the first periodic signal and the unit data,

the controller-side interface circuit transmits a periodic signal transmission command for instructing transmission of the first periodic signal to the memory-side interface circuit after the transmission of the read command, and

the memory-side interface circuit transmits the first periodic signal having a predetermined number of cycles in accordance with the periodic signal transmission command.
(3)

The interface circuit according to (1),

wherein the controller-side interface circuit transmits a read command for instructing reading of the read data to the memory-side interface circuit, and

the memory-side interface circuit reads the read data in accordance with the read command, synchronizes the unit data with the first periodic signal having the same number of cycles as the number of pieces of the unit data, and sequentially transmits the first periodic signal and the unit data, and further transmits the first periodic signal having a predetermined number of cycles.
(4)

The interface circuit according to (3), wherein, in a non-transmission period in which the read data is not transmitted, the memory-side interface circuit repeatedly transmits the first periodic signal until the number of cycles transmitted within the non-transmission period reaches the predetermined number of cycles.
(5)

The interface circuit according to (3) or (4), wherein the controller-side interface circuit transmits a setting command for setting a predetermined number of cycles to the memory-side interface circuit.
(6)

The interface circuit according to (5),

wherein the controller-side interface circuit transmits a start command for instructing transmission of a predetermined number of pieces of pattern data to the memory-side interface circuit,

the memory-side interface circuit synchronizes the first periodic signal having the same number of cycles as the predetermined number with the pattern data in accordance with the start command, and transmits the first periodic signal and the pattern data to the controller-side interface circuit, and

the controller-side interface circuit sequentially holds the transmitted pattern data in the holding units of the plurality of stages in synchronization with the first periodic signal, sequentially reads the held pattern data in synchronization with the second periodic signal, and transmits the setting command for setting a difference between the number of pieces of the read pattern data and the predetermined number to the memory-side interface circuit.
(7)

The interface circuit according to any of (1) to (6),

wherein the unit data includes first and second data, and

the memory-side interface circuit transmits the first data in synchronization with a rise of the first periodic signal, and transmits the second data in synchronization with a fall of the first periodic signal.
(8)

A memory device including:

a memory cell; and

an interface circuit configured to synchronize a periodic signal having a greater number of cycles than a number of pieces of unit data obtained by dividing read data read from the memory cell by a predetermined unit with the unit data and to sequentially transmit the periodic signal and the unit data.
(9)

An information processing system including:

a memory cell;

a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and

a controller-side interface circuit configured to sequentially hold the transmitted unit data in holding units of a plurality of stages in synchronization with the first periodic signal and to sequentially read and output the held unit data in synchronization with a second periodic signal.
(10)

An interface circuit control method including:

a transmission procedure of a memory-side interface circuit in which a first periodic signal having a greater number of cycles than a number of pieces of unit data obtained by dividing read data read from a memory cell by a predetermined unit is synchronized with the unit data and the first periodic signal and the unit data are sequentially transmitted, and

a reception procedure of a controller-side interface circuit in which the transmitted unit data is sequentially held in holding units of a plurality of stages in synchronization with the first periodic signal and the held unit data is sequentially read and output in synchronization with a second periodic signal.

### REFERENCE SIGNS LIST

100 host computer
200 storage
300 memory controller
301 host interface circuit
302 RAM
303 CPU
304 ECC processing unit
305 ROM
306, 405 bus
311 access command issuing unit
312 strobe issuance instructing unit
313 calibration processing unit
314 number-of-strobe-issuance-operations setting unit
320 controller-side interface circuit
325 clock-enable transmission unit
326, 369-1 inverter
327, 337, 355, 356, 357, 360, 361, 363, 365, 366, 368, 369, 417, 438, 452, 453, 455, 456 flip-flop
328, 338, 403, 436 driver
330 chip-select transmission unit
331 command/address transmission unit
335 clock transmission unit
336 buffer
340 strobe transmission unit
341, 371, 440, 460 data transmission unit
350, 372, 450, 461 data reception unit
351, 352, 416, 430, 451, 454 receiver
353 delay synchronization circuit
354 serial/parallel conversion unit
358 clock transfer unit
359, 364 switch
362, 367, 437 selector
370 clock generation unit
381, 382, 383, 384, 385, 386, 387, 471, 472, 473, 474, 475, 476, 477 terminal
400 non-volatile memory
401 data buffer
402 memory cell array
404 address decoder
410 memory-side interface circuit
415 clock-enable reception unit
420 chip-select reception unit
425 command/address reception unit
435 strobe transmission unit
480 memory control unit
481 command buffer
482 command decoder
483 access control unit
484, 485 strobe signal issuing unit
486 number-of-strobe-issuance-operations register
487 adjustment pattern generation unit
488 measurement pattern generation unit

1. An interface circuit comprising:
a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and
a controller-side interface circuit configured to sequentially hold the transmitted unit data in holding units of a plurality of stages in synchronization with the first periodic signal and to sequentially read and output the held unit data in synchronization with a second periodic signal.

2. The interface circuit according to claim 1,
wherein the controller-side interface circuit transmits a read command for instructing reading of the read data to the memory-side interface circuit,
the memory-side interface circuit reads the read data in accordance with the read command, synchronizes the unit data with the first periodic signal having the same number of cycles as the number of pieces of the unit data, and sequentially transmits the first periodic signal and the unit data,
the controller-side interface circuit transmits a periodic signal transmission command for instructing transmission of the first periodic signal to the memory-side interface circuit after the transmission of the read command, and
the memory-side interface circuit transmits the first periodic signal having a predetermined number of cycles in accordance with the periodic signal transmission command.

3. The interface circuit according to claim 1,
wherein the controller-side interface circuit transmits a read command for instructing reading of the read data to the memory-side interface circuit, and
the memory-side interface circuit reads the read data in accordance with the read command, synchronizes the unit data with the first periodic signal having the same number of cycles as the number of pieces of the unit data, and sequentially transmits the first periodic signal and the unit data, and further transmits the first periodic signal having a predetermined number of cycles.

4. The interface circuit according to claim 3, wherein, in a non-transmission period in which the read data is not transmitted, the memory-side interface circuit repeatedly transmits the first periodic signal until the number of cycles transmitted within the non-transmission period reaches the predetermined number of cycles.

5. The interface circuit according to claim 3, wherein the controller-side interface circuit transmits a setting command for setting a predetermined number of cycles to the memory-side interface circuit.

6. The interface circuit according to claim 5,
wherein the controller-side interface circuit transmits a start command for instructing transmission of a predetermined number of pieces of pattern data to the memory-side interface circuit,
the memory-side interface circuit synchronizes the first periodic signal having the same number of cycles as the predetermined number with the pattern data in accordance with the start command, and transmits the first periodic signal and the pattern data to the controller-side interface circuit, and
the controller-side interface circuit sequentially holds the transmitted pattern data in the holding units of the plurality of stages in synchronization with the first periodic signal, sequentially reads the held pattern data in synchronization with the second periodic signal, and transmits the setting command for setting a difference between the number of pieces of the read pattern data and the predetermined number to the memory-side interface circuit.

7. The interface circuit according to claim 1,
wherein the unit data includes first and second data, and
the memory-side interface circuit transmits the first data in synchronization with a rise of the first periodic signal, and transmits the second data in synchronization with a fall of the first periodic signal.

8. A memory device comprising:
a memory cell; and
an interface circuit configured to synchronize a periodic signal having a greater number of cycles than a number of pieces of unit data obtained by dividing read data read from the memory cell by a predetermined unit with the unit data and to sequentially transmit the periodic signal and the unit data.

9. An information processing system comprising:
a memory cell;
a memory-side interface circuit configured to synchronize a first periodic signal having a greater number of cycles than a number of pieces of unit data obtained by dividing read data read from a memory cell by a predetermined unit with the unit data and to sequentially transmit the first periodic signal and the unit data; and
a controller-side interface circuit configured to sequentially hold the transmitted unit data in holding units of a plurality of stages in synchronization with the first periodic signal and to sequentially read and output the held unit data in synchronization with a second periodic signal.

10. An interface circuit control method comprising:
a transmission procedure of a memory-side interface circuit in which a first periodic signal having a greater number of cycles than a number of pieces of unit data obtained by dividing read data read from a memory cell by a predetermined unit is synchronized with the unit data and the first periodic signal and the unit data are sequentially transmitted, and
a reception procedure of a controller-side interface circuit in which the transmitted unit data is sequentially held in holding units of a plurality of stages in synchronization with the first periodic signal and the held unit data is sequentially read and output in synchronization with a second periodic signal.
